(19) United States
(12) Patent Application Publication
(10) Pub. No.: US 2010/0193833 A1
(43) Pub. Date: Aug. 5, 2010

(54) Nitride-Based Semiconductor Device, Light Apparatus, and Method of Manufacturing Nitride-Based Semiconductor Device

(75) Inventors: Yasuto MIYAKE, Osaka (JP); Yasumitsu KUNOH, Tottori-shi (JP); Masayuki HATA, Osaka (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/697,948

(22) Filed: Feb. 1, 2010

(30) Foreign Application Priority Data
Feb. 5, 2009 (JP) 2009-25062
Jan. 27, 2010 (JP) 2010-15085

(51) Int. Cl. H01L 33/30; H01L 29/20; H01L 21/30

(52) U.S. Cl. 257/103; 257/615; 438/462; 257/E29.089; 257/E33.023; 257/E21.211

(57) ABSTRACT

A nitride-based semiconductor device includes a substrate made of a nitride-based semiconductor, a device layer formed on the substrate, and an electrode formed on a surface of the substrate opposite to the device layer. The substrate includes a first surface having a nonpolar plane or a semipolar plane, a second surface opposite to the first surface, a defect concentration region extending in a direction inclined with respect to a normal direction of the first surface from the first surface toward the second surface and penetrating to the second surface and a current path region separated from other region of the substrate by the defect concentration region employed as a boundary, the defect concentration region is not exposed on the first surface, and the electrode is formed on the second surface in the current path region.

### CROSS-REFERENCE TO RELATED APPLICATIONS

The priority application number JP2009-025062, Nitride-Based Semiconductor Device and Method of Manufacturing the Same, Feb. 5, 2009, Yasuto Miyake et al, JP2010-015085, Nitride-Based Semiconductor Device, Light Apparatus, and Method of Manufacturing Nitride-Based Semiconductor Device, Jan. 27, 2010, Yasuto Miyake et al, upon which this patent application is based is hereby incorporated by reference.

### BACKGROUND OF THE INVENTION

1. Field of the Invention

The present invention relates to a nitride-based semiconductor device, a light apparatus, and a method of manufacturing nitride-based semiconductor device, and more particularly, it relates to a nitride-based semiconductor device comprising a substrate including a defect concentration region, a light apparatus and a method of manufacturing the nitride-based semiconductor device.

2. Description of the Background Art

A nitride-based semiconductor device employing a nitride-based semiconductor substrate including a defect concentration region is proposed in general, as disclosed in Japanese Patent Laying-Open No. 2003-133649, for example.

The aforementioned Japanese Patent Laying-Open No. 2003-133649 discloses a method of manufacturing an ingot having a defect concentration region with a high defect density by concentrating defects on a prescribed region when forming a nitride-based semiconductor substrate by growth and a low defect density region with a low defect density due to concentration of the defects on the defect concentration region. This Japanese Patent Laying-Open No. 2003-133649 discloses a method of manufacturing a nitride-based semiconductor device in which a substrate including a defect concentration region extending to a lower surface of the substrate in a direction perpendicular to a main surface (upper surface) is formed by slicing the aforementioned ingot in a growth direction of the ingot and a vertical direction, a semiconductor light-emitting device layer is provided on an upper surface of the substrate, and an electrode is provided on the lower surface of the substrate.

In the aforementioned nitride-based semiconductor device disclosed in Japanese Patent Laying-Open No. 2003-133649, however, the main surface (upper surface) of the substrate is a (0001) plane which is a polar plane, and hence, in a case of the light-emitting device formed with the nitride-based semiconductor device including a light-emitting layer on the main surface, a piezoelectric field is generated in the light-emitting layer formed by crystal growth and luminous efficiencies are disadvantageously reduced.

In a case of a nitride-based semiconductor device constituting a field-effect transistor (FET) device by forming a nitride-based semiconductor device layer on the substrate, electrons are induced by the piezoelectric field, and a normally-off operation can not be performed between a source and a drain of the FET, and hence it can not be disadvantageously applied to a power device and the like requiring the normally-off operation.

Thus, in the nitride-based semiconductor device formed with the device layer on the upper surface of the substrate which is the polar plane, and a bad influence is disadvantageously exerted on a normal operation of the device due to the piezoelectric field.

As described in the aforementioned Japanese Patent Laying-Open No. 2003-133649, in the defect concentration region, the polarity may be inverted with respect to the low defect density region. In this case, no crystal is continuous on a boundary between the defect concentration region and the low defect density region. Thus, a current flow is blocked in a direction across the boundary between the low defect density region and the defect concentration region, and hence electric resistance in traversing the defect concentration region is disadvantageously increased.

### SUMMARY OF THE INVENTION

A nitride-based semiconductor device according to a first aspect of the present invention comprises a substrate made of a nitride-based semiconductor, a device layer made of the nitride-based semiconductor formed on the substrate and an electrode formed on a surface of the substrate opposite to the device layer, wherein the substrate includes a first surface having a nonpolar plane or a semipolar plane, a second surface which is a surface opposite to the first surface, a defect concentration region extending in a direction inclined with respect to a normal direction of the first surface and penetrating to the second surface and a current path region having the first surface formed with the device layer and the second surface and separated from other region of the substrate by the defect concentration region employed as a boundary, the defect concentration region is not exposed on the first surface, and the electrode is formed on the second surface in the current path region.

In this case, the nonpolar plane in the present invention is a plane parallel to a normal direction of the (0001) plane and a plane inclined by up to about 15 degree from these planes. The semipolar plane in the present invention is a plane inclined by at least about 30 degrees and not more than about 75 degrees from a (0001±1) plane, and a {11-22} plane, a {11-2-2} plane, a {1-101} plane, a {1-10-1} plane, or the like, for example.

In this nitride-based semiconductor device according to the first aspect of the present invention, as hereinabove described, the first surface of the substrate is the nonpolar plane or the semipolar plane, and hence a piezoelectric field generated in the nitride-based semiconductor device layer can be reduced, and a bad influence to a normal operation of the device due to the piezoelectric field can be suppressed. In the nitride-based semiconductor device according to the first aspect, on the current path region arranged on a first side of the defect concentration region, the device layer is formed on the first surface and the electrode is formed on the second surface, and hence a current between the device layer and the electrode can flow without traversing the defect concentration region, and increase of electric resistance resulting from the defect concentration region can be suppressed.

In the aforementioned nitride-based semiconductor device according to the first aspect, the device layer preferably includes a current injection portion, and a center in a width direction of the current injection portion is preferably located above the second surface in the current path region. According to this structure, a current flowing from the current injection portion into the electrode on the second surface without traversing the defect concentration region is increased, and hence increase of electric resistance resulting from the defect concentration region can be further suppressed.

In the aforementioned nitride-based semiconductor device according to the first aspect, the substrate further preferably includes a non-current path region as the other region, and the electrode is preferably formed on a region from the second surface in the current path region to the second surface in the non-current path region. According to this structure, a current flows from the device layer into the electrode on the second surface in the non-current path region across the defect concentration region in addition to the current flowing from the device layer into the current on the second surface in the current path region, and hence electric resistance between the device layer and the electrode can be further suppressed.

In the aforementioned nitride-based semiconductor device according to the first aspect, the device layer preferably includes a current injection portion, and the defect concentration region is preferably inclined in a direction closer to the current injection portion toward the second surface, and a center in a width direction of the current injection portion is preferably located in a direction separated from the defect concentration region with respect to a center in a width direction of the first surface. According to this structure, a center of the current flowing from the current injection portion to the electrode can be separated from the defect concentration region. Thus, a current flowing from the current injection portion into the electrode on the second surface without traversing the defect concentration region is increased, and hence increase of electric resistance resulting from the defect concentration region can be further suppressed.

In the aforementioned nitride-based semiconductor device according to the first aspect, the substrate preferably further includes a recess portion formed on a side end side of the first surface, and the defect concentration region preferably penetrates from the recess portion to the second surface. According to this structure, the defect concentration region extends to the recess portion located on the side end of the first surface formed with the device layer, and hence the device layer is separated from the portion where the defect concentration region appears, and hence propagation of cracks or dislocations from the defect concentration region to the device layer can be suppressed.

In the aforementioned structure in which the substrate further includes the recess portion, a depth of the recess portion is preferably larger than a thickness of the device layer. According to this structure, the non-device layer formed in the recess portion when forming the device layer is linked with or divided from the device layer through the thin layer, and hence propagation of cracks or dislocations from the defect concentration region to the device layer can be suppressed.

In the aforementioned nitride-based semiconductor device according to the first aspect, the first surface is preferably a (10-10) plane, a (2-1-10) plane, or a plane substantially equal to a plane equivalent to these planes. According to this structure, the device layer can be formed on the first surface consisting of the nonpolar plane of the substrate described above, and hence a piezoelectric field can be hardly generated in the device layer.

In the aforementioned nitride-based semiconductor device according to the first aspect, the defect concentration region is preferably formed substantially parallel to a (H, K, −H−K, 0) plane (when at least either one of H and K is a nonzero integer). According to this structure, in the manufacturing process, the nitride-based semiconductor including the defect concentration regions is sliced by the suitable slice plane when forming the wafer substrate including the defect concentration region, whereby the first surface consisting of the nonpolar plane can be easily formed on the surface of the wafer substrate.

A light apparatus comprises a nitride-based semiconductor device including a substrate made of a nitride-based semiconductor, a light-emitting device layer made of the nitride-based semiconductor formed on the substrate and an electrode formed on a surface of the substrate opposite to the light-emitting device layer, and an optical system controlling light emitted from the nitride-based semiconductor device, wherein the substrate has a first surface having a nonpolar plane or a semipolar plane, a second surface which is a surface opposite to the first surface, a defect concentration region extending in a direction inclined with respect to a normal direction of the first surface from the first surface toward the second surface and penetrating to the second surface, and a current path region having the first surface formed with the light-emitting device layer and the second surface and separated from other region of the substrate by the defect concentration region employed as a boundary, the defect concentration region is exposed on the first surface, and the electrode is formed on the second surface in the current path region.

In this light apparatus according to a second aspect of the present invention, as hereinabove described, the first surface of the substrate is the nonpolar plane or the semipolar plane, and hence the piezoelectric field generated in the light-emitting device layer made of the nitride-based semiconductor can be reduced, and the light apparatus in which a bad influence to a normal operation of the device due to a piezoelectric field is suppressed can be obtained. On the current path region arranged on a first side of the defect concentration region, the light-emitting device layer is formed on the first surface and the electrode is formed on the second surface, and hence a current between the light-emitting device layer and the electrode can flow without traversing the defect concentration region, and the light apparatus in which increase of electric resistance resulting from the defect concentration region is suppressed can be obtained.

A method of manufacturing a nitride-based semiconductor device according to a third aspect of the present invention comprises steps of forming a wafer substrate made of a nitride-based semiconductor having defect concentration regions extending in a direction inclined with respect to a normal direction of a first surface and penetrating from the first surface having a nonpolar plane or a semipolar plane to a second surface which is a surface opposite to the first surface, forming a device layer made of the nitride-based semiconductor on the first surface, and dividing the wafer substrate into a plurality of devices, wherein the dividing step includes a step of dividing the wafer substrate so as not to expose the defect concentration regions on the first substrates of the devices.

In the method of manufacturing a nitride-based semiconductor device according to the third aspect of the present invention, the aforementioned nitride-based semiconductor device according to the first aspect can be manufactured.

The aforementioned method of manufacturing a nitride-based semiconductor device according to the third aspect preferably further comprises a step of forming grooves on portions, where the defect concentration regions appear, of the first surface in advance of the step of forming the device layer on the first surface of the wafer substrate. According to this structure, the grooves are formed on the portions, where the defect concentration regions appear, of the first surface and thereafter the device layer is formed on the first surface, and hence the non-device layer formed in the grooves is linked with or separated from the device layer through the thin layer by the steps of the grooves. Therefore, propagation of cracks or dislocations from the defect concentration regions in the grooves to the device layer can be suppressed when forming the device layer, and the device layer having a small number of the cracks or the dislocations can be formed.

In the aforementioned method of manufacturing a nitride-based semiconductor device according to the third aspect, the dividing step preferably includes a step of dividing the wafer substrate in the grooves on the grooves. According to this structure, division is easily performed and excess force is difficult to be applied to the semiconductor device layer in division by dividing the wafer substrate into a plurality of devices along the grooves which are thin portions of the wafer substrate, and hence separation of or damage to the device layer can be suppressed.

In the aforementioned structure including the step of dividing the wafer substrate in the grooves, the dividing step preferably includes a step of dividing the wafer substrate on cut planes along inner side surfaces of the grooves. According to this structure, the wafer substrate can be easily divided along positions where the inner side surfaces of the grooves are formed.

In this case, the dividing step preferably includes a step of dividing the wafer substrate on the cut planes along the inner side surfaces not including the defect concentration regions. According to this structure, breakage of the nitride-based semiconductor laser device caused by chipping the wafer substrate on the defect concentration region can be suppressed dissimilarly to a case where the wafer substrate is divided along the inner side surfaces including the defect concentration regions, and hence a yield can be improved.

In the aforementioned structure further comprising the step of forming the grooves, the dividing step preferably includes a step of dividing the wafer substrate so that the devices do not include the grooves. According to this structure, the nitride-based semiconductor device including no grooves on side ends of the device can be formed, and hence a width of the nitride-based semiconductor device can be reduced.

In the aforementioned structure further comprising the step of forming the grooves, a depth of each of the grooves is preferably larger than a thickness of the device layer. According to this structure, the non-device layer formed in the grooves when forming the device layer are linked with or divided from the device layer through the thin layer, and hence the nitride-based semiconductor device in which propagation of cracks or dislocations from the defect concentration regions to the device layer is suppressed can be obtained.

In the aforementioned method of manufacturing a nitride-based semiconductor device according to the third aspect, the dividing step includes a step of dividing the wafer substrate on regions, where the defect concentration regions do not appear, of the first surface. According to this structure, the defect concentration regions do not appear on the first substrate, and hence a current path region of the wafer substrate formed with the semiconductor device layer on an upper side can be widely ensured.

In the aforementioned method of manufacturing a nitride-based semiconductor device according to the third aspect, the dividing step preferably includes a step of exposing the defect concentration regions on side facets of the wafer substrate. According to this structure, the device can be so formed that the defect concentration regions are exposed on the side facets of the wafer substrate, and hence the width of the device can be reduced.

In the aforementioned method of manufacturing a nitride-based semiconductor device according to the third aspect, the dividing step preferably includes a step of exposing the defect concentration regions on both side facets of the wafer substrate by dividing the wafer substrate along the defect concentration regions. According to this structure, the nitride-based semiconductor device is divided along the defect concentration regions, and hence the defect concentration regions exist only on the both sides of the substrate, and the overall first and second surfaces of the substrate are not divided by the defect concentration regions. In other words, the substantially overall second surface of the substrate serves as the current path surface, and a plane area of the electrode on the current path surface can be increased, and hence the nitride-based semiconductor device in which electric resistance is further reduced can be obtained.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor laser device of a first embodiment of the present invention;

FIG. 2 is a top plan view of the semiconductor laser device of the first embodiment of the present invention;

FIG. 3 is a perspective view of a substrate of the semiconductor laser device of the first embodiment of the present invention;

FIG. 4 is a bottom plan view of the substrate of the semiconductor laser device of the first embodiment of the present invention;

FIG. 5 is a sectional view for illustrating a manufacturing process of a wafer substrate of the semiconductor laser device of the first embodiment of the present invention;

FIG. 6 is a top plan view for illustrating a manufacturing process of the wafer substrate of the semiconductor laser device of the first embodiment of the present invention;

FIG. 7 is a perspective view of the wafer substrate of the semiconductor laser device of the first embodiment;

FIG. 8 is a sectional view of the wafer substrate of the semiconductor laser device of the first embodiment;

FIGS. 9 to 11 are sectional views for illustrating the manufacturing process of the semiconductor laser device of the first embodiment;

FIG. 12 is a top plan view for illustrating the manufacturing process of the semiconductor laser device of the first embodiment;

FIG. 13 is a sectional view for illustrating the manufacturing process of the semiconductor laser device of the first embodiment;

FIG. 14 is a top plan view for illustrating the manufacturing process of the semiconductor laser device of the first embodiment;

FIG. 15 is a sectional view for illustrating the manufacturing process of the semiconductor laser device of the first embodiment;

FIG. 16 is a sectional view showing a structure of a semiconductor laser device of a second embodiment of the present invention;

FIG. 17 is a sectional view for illustrating a manufacturing process of the semiconductor laser device of the second embodiment;

FIG. 18 is a sectional view showing a structure of a semiconductor laser device of a third embodiment of the present invention;

FIG. 19 is a sectional view for illustrating a manufacturing process of the semiconductor laser device of the third embodiment;

FIG. 20 is a sectional view showing a structure of a semiconductor laser device of a fourth embodiment of the present invention;

FIG. 21 is a sectional view for illustrating a manufacturing process of the semiconductor laser device of the fourth embodiment;

FIG. 22 is a sectional view showing a structure of a semiconductor laser device of a fifth embodiment of the present invention;

FIG. 23 is a block diagram of an optical pickup having a build-in semiconductor laser apparatus mounted with a semiconductor laser device according to a sixth embodiment of the present invention;

FIG. 24 is an external perspective view showing a schematic structure of the semiconductor laser apparatus mounted with the semiconductor laser device according to the sixth embodiment of the present invention;

FIG. 25 is a front elevational view of a state where a lid body of a can package of the semiconductor laser apparatus mounted with the semiconductor laser device according to the sixth embodiment of the present invention is removed;

FIG. 26 is a block diagram of an optical disc apparatus comprising an optical pickup mounted with a semiconductor laser device according to a seventh embodiment of the present invention;

FIG. 27 is a front elevational view showing a structure of a semiconductor laser apparatus mounted with a semiconductor laser device according to an eighth embodiment of the present invention;

FIG. 28 is a block diagram of a projector mounted with a semiconductor laser device according to the eighth embodiment of the present invention;

FIG. 29 is a block diagram of a projector mounted with a semiconductor laser device according to a ninth embodiment of the present invention;

FIG. 30 is a timing chart showing a state where a control portion transmits signals in a time-series manner in the projector mounted with the semiconductor laser device according to the ninth embodiment of the present invention;

FIG. 31 is a sectional view of a substrate of a semiconductor laser device according to a first modification of the present invention;

FIG. 32 is a sectional view of a substrate of a semiconductor laser device according to a second modification of the present invention;

FIG. 33 is a sectional view of a substrate of a semiconductor laser device according to a third, modification of the present invention;

FIG. 34 is a sectional view of a substrate of a semiconductor laser device according to a fourth modification of the present invention; and

FIG. 35 is a sectional view of a substrate of a semiconductor laser device according to a fifth modification of the present invention.

### DESCRIPTION OF THE PREFERRED EMBODIMENTS

Embodiments of the present invention will be hereinafter described with reference to the drawings.

### First Embodiment

A structure of a semiconductor laser device 100 according to a first embodiment will be now described with reference to FIGS. 1 to 4. In the first embodiment, the “nitride-based semiconductor device” of the present invention is applied to the semiconductor laser device 100.

As shown in FIG. 1, the semiconductor laser device 100 of the first embodiment is a laser device emitting a blue-violet laser beam of about 405 nm, and comprises a substrate 10, a semiconductor device layer 20, a p-side ohmic electrode 29, a current blocking layer 30, a p-side pad electrode 31 and an n-side electrode 45.

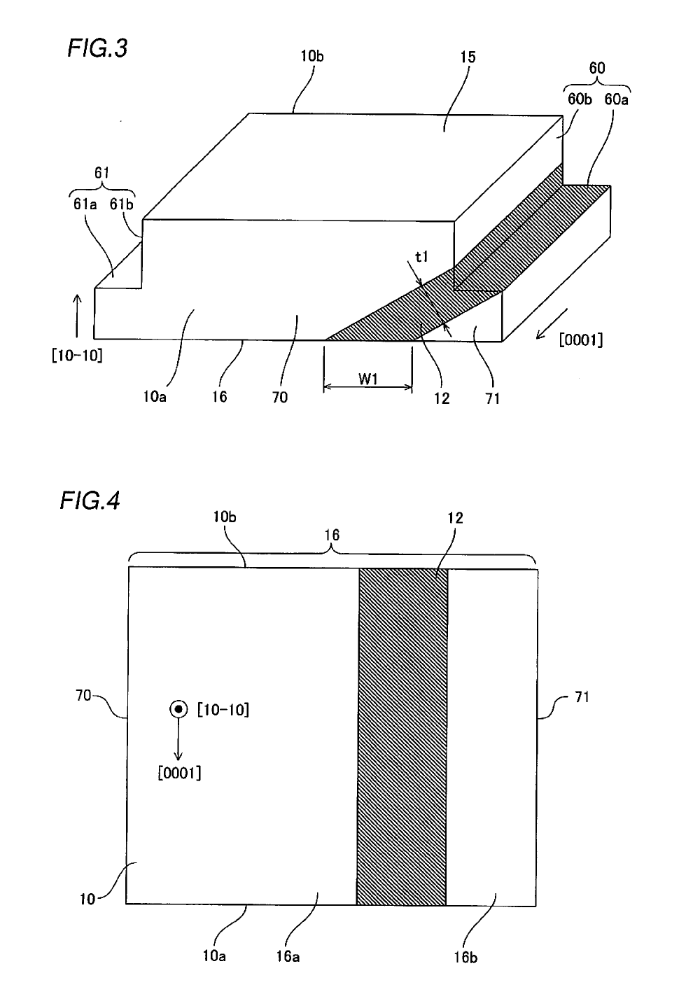

The substrate 10 is made of n-type gallium nitride (GaN), and has a thickness of about 100 μm and a width of about 400 μm. According to the first embodiment, an upper surface 15 of the substrate 10 is a nonpolar plane, and is formed by a (10-10) plane inclined by about 30 degrees from a [11-20] direction to a [1-100] direction about an axis along a [0001] direction with respect to a (11-20) plane. In the substrate 10, a defect concentration region 12 has a surface parallel to the (11-20) plane, and the defect concentration region 12 spreads in the form of a surface in the [0001] direction from a front facet 10a of the substrate 10 to a rear facet 10b, as shown in FIG. 3.

As shown in FIG. 1, the defect concentration region 12 extends in a direction closer to a ridge portion 50 from the upper surface 15 of the substrate 10 toward a lower surface 16 while inclining by about 60 degrees with respect to a normal direction of the upper surface 15 of the substrate 10. The defect concentration region 12 is a region formed by concentrating defects in the form of the surface along the [1-100] direction from the lower surface 16 of the substrate 10 toward the upper surface 15.

As shown in FIGS. 1 and 3, a pair of recess portions and 61 are formed on both side ends of the upper surface 15 of the substrate 10 to extend in the [0001] direction from the front facet 10a of the substrate 10 to the rear facet 10b. A depth of each of the recess portions 60 and 61 is about 5 μm, and a width of each of bottom surfaces 60a and 61a of the recess portions 60 and 61 is about 55 μm. The defect concentration region 12 extends to penetrate from the lower surface 16 of the substrate toward the recess portion 60 among the pair of recess portions 60 and 61, and extends in the form of the surface in the [0001] direction from the front facet 10a of the substrate 10 to the rear facet 10b. While the defect concentration region 12 appears on both of the bottom surface 60a and a side surface 60b of the recess portion 60, the defect concentration region 12 does not appear on portions of the substrate on the upper surface 15 side in the side surface 60b.

The substrate 10 is separated into the current path region 70 and the non-current path region 71 (other region) by the defect concentration region 12 employed as a boundary. The current path region 70 is constituted by a region from an overall area of the upper surface 15 to a part of the lower surface 16 (current path surface 16a). The non-current path region 71 is constituted by a region from the bottom surface 60a of the recess portion 60 to a remaining portion (non-current path surface 16b) of the lower surface 16. As shown in FIG. 4, the lower surface 16 of the substrate 10 is separated into the current path surface 16a on the current path region 70 side and the non-current path surface 16b on the non-current path region 71 side by the defect concentration region 12.

In the defect concentration region 12, a thickness t1 in a direction perpendicular to a surface of the defect concentration region 12 shown in FIG. 3 is at least about 20 μm and not more than about 50 μm, and a width W1 of the defect concentration region 12 appearing on the lower surface 16 of the substrate 10 is at least about 40 μm and not more than about 100 μm. For example, when the thickness of the defect concentration region 12 is about 50 μm, the width of the portion, appearing on the lower surface 16 of the substrate, of the defect concentration region 12 is about 100 μm, and the position thereof is in the range of at least about 120 μm and not more than about 220 μm from a side facet of the substrate 10 on the recess portion 60 side. Thus, the portion, appearing on the lower surface 16 of the substrate, of the defect concentration region 12 reaches a position of about 200 μm from the side facet of the substrate 10 on the recess portion 60 side, which is a center in a width direction of the substrate 10.

As shown in FIG. 1, the semiconductor device layer 20 is formed on the overall area of the upper surface 15, and includes a buffer layer 21 made of Al_{0.01}Ga_{0.99}N, having a thickness of about 1.0 μm and formed on the upper surface 15 of the substrate 10, an n-side cladding layer 22 made of n-type Al_{0.07}Ga_{0.93}N doped with Ge, having a thickness of about 1.9 μm and formed on the buffer layer 21, and an n-side carrier blocking layer 23 made of Al_{0.2}Ga_{0.8}N having a thickness of about 20 nm and formed on the n-side cladding layer 22 and a light-emitting layer 24 formed on the n-side carrier blocking layer 23.

The light-emitting layer 24 has a multiple quantum well (MQW) structure. More specifically, the light-emitting layer 24 consists of an MQW active layer obtained by alternately stacking three quantum well layers made of InₓGa₁₋ₓN, each having a thickness of about 2.5 nm and three quantum barrier layers made of In_{y}Ga_{1-y}N, each having a thickness of about 20 nm. In this embodiment, x>y, and x=0.15 and y=0.02.

The semiconductor device layer 20 further includes a p-side optical guide layer 25 made of In_{0.01}Ga_{0.99}N, having a thickness of about 80 nm and formed on the light-emitting layer 24, a p-side carrier blocking layer 26 made of Al_{0.25}Ga_{0.75}N, having a thickness of about 20 nm and formed on the p-side optical guide layer 25, a p-type cladding layer 27 made of Al_{0.07}Ga_{0.93}N doped with Mg, having a thickness of about 0.5 μm and formed on the p-side carrier blocking layer 26 and a p-side contact layer 28 made of In_{0.07}Ga_{0.93}N, having a thickness of about 3 nm and formed on the p-type cladding layer 27.

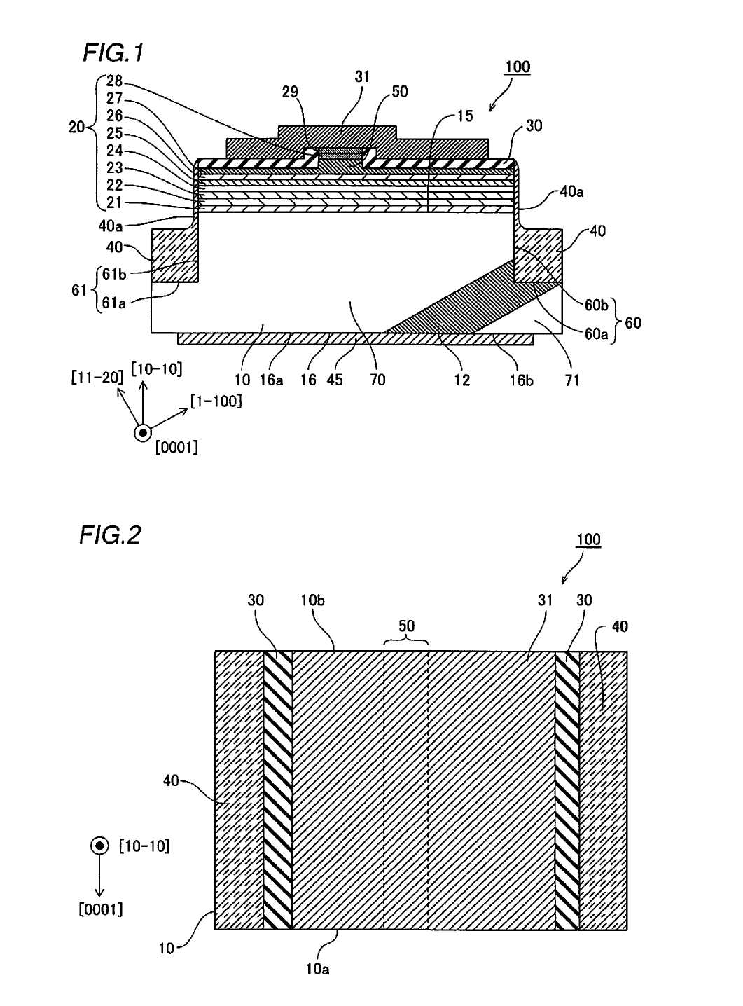

The p-type cladding layer 27 is provided with a projecting portion 27a having a width of about 2 μm and a thickness of about 0.4 μm. The p-side contact layer 28 is formed on the projecting portion 27a of the p-type cladding layer 27. The ridge portion 50 is formed by the projecting portion 27a of the p-type cladding layer 27 and the p-side contact layer 28. The ridge portion 50 is formed in a striped manner to extend in the [0001] direction from the front facet 10a of the substrate 10 to the rear facet 10b (see FIG. 2).

A central position in the width direction of the projecting portion 27a of the p-type cladding layer 27 is located in a direction separated from the recess portion 60, to which the defect concentration region 12 extends, by about 25 μm with respect to the position of about 200 μm from the facet of the substrate 10 on the recess portion 60, which is the central position in the width direction of the upper surface 15 of the substrate 10, and no defect concentration region 12 is located below the central position in the width direction of the projecting portion 27a. In other words, the center in the width direction of the projecting portion 27a (center in the width direction of the ridge portion 50) is located above the current path surface 16a among the lower surface 16 of the substrate.

The p-side ohmic electrode 29 in which a Pt layer having a thickness of about 5 nm, a Pd layer having a thickness of about 100 nm and an Au layer having a thickness of about 150 nm are formed from the lower layer side toward the upper layer side is formed on the p-type contact layer 28. The current blocking layer 30 made of SiO₂, having a thickness of about 0.2 μm is formed to cover the upper surface of the p-type cladding layer 27 and side surfaces of the ridge portion 50 and the p-side ohmic electrode 29. The p-side pad electrode 31 in which a Ti layer having a thickness of about 100 nm, a Pd layer having a thickness of about 100 nm and an Au layer having a thickness of about 3 μm are formed in this order from the lower layer side to the upper layer side is formed on the lower surface 16 of the substrate 10 is formed on the upper surface of the p-side ohmic electrode 29 and the upper surface of the current blocking layer 30.

Thus, a current supplied to the p-side pad electrode 31 is supplied to the light-emitting layer 24 in the semiconductor device layer 20 through the p-side ohmic electrode 29 not insulated by the current blocking layer 30 and the ridge portion 50 constituted by the p-side contact layer 28 and the projecting portion 27a of the p-type cladding layer 27. In other words, the ridge portion 50 is a current injection portion for supplying a current to the light-emitting layer of the semiconductor device layer 20, and the portion located below the ridge portion 50 in the light-emitting layer 24 is a light-emitting portion.

The n-side electrode 45 in which an Al layer having a thickness of about 10 nm, a Pt layer having a thickness of about 20 nm, and an Au layer having a thickness of about 300 nm are formed in this order from the lower surface 16 side of the substrate 10 on the lower surface 16 of the substrate 10 is formed on the lower surface 16 from the current path surface 16a of the substrate 10 to the non-current path surface 16b.

A non-device layer 40 is formed on the bottom surfaces 60a and 61a and the side surfaces 60b and 61b of the recess portions 60 and 61 of the substrate 10. The non-device layer 40 is formed in the recess portion 60 simultaneously when the semiconductor device layer 20 is formed on the upper surface 15 of the substrate 10, and is formed with a thin layer 40a thinner than a layer formed on the bottom surface 60a on the side surface 60b of the recess portion 60 and the side facets of the semiconductor device layer 20. A length from the upper surface 15 of the substrate 10 to the bottom surface 60a of the recess portion 60 (depth of the recess portion 60) is about 5 μm and is larger than a thickness (about 3 μm) of the semiconductor device layer 20. In other words, the thickness of the non-device layer 40 formed on the bottom surface 60a of the recess portion 60 has substantially the same thickness as that of the semiconductor device layer 20, and hence a depth of the recess portion 60 is larger than that of the non-device layer 40 on the bottom surface 60a. The thickness of the semiconductor device layer 20 shows a length from the upper surface 15 of the substrate 10, i.e., the lower surface of the buffer layer 21 to the upper surface of the p-side contact layer 28 of the ridge portion 50.

Thus, the semiconductor device layer 20 on the upper surface 15 of the substrate 10 and the non-device layer 40 on the bottom surface 60a of the recess portion are linked with each other through the thin layer 40a of the non-device layer 40 formed on the side surface 60b of the recess portion 60.

The substrate 10, the semiconductor device layer 20, the light-emitting layer 24, the n-side electrode 45, the upper surface 15, the lower surface 16, the defect concentration region 12, the current path region 70, the non-current path region 71, the recess portion 60 and the ridge portion 50 are examples of the “substrate”, the “device layer”, the “light-emitting device layer”, the “electrode”, the “first surface”, the “second surface”, the “defect concentration region”, the “current path region”, the “non-current path region”, the “recess portion” and the “current injection portion” in the present invention, respectively.

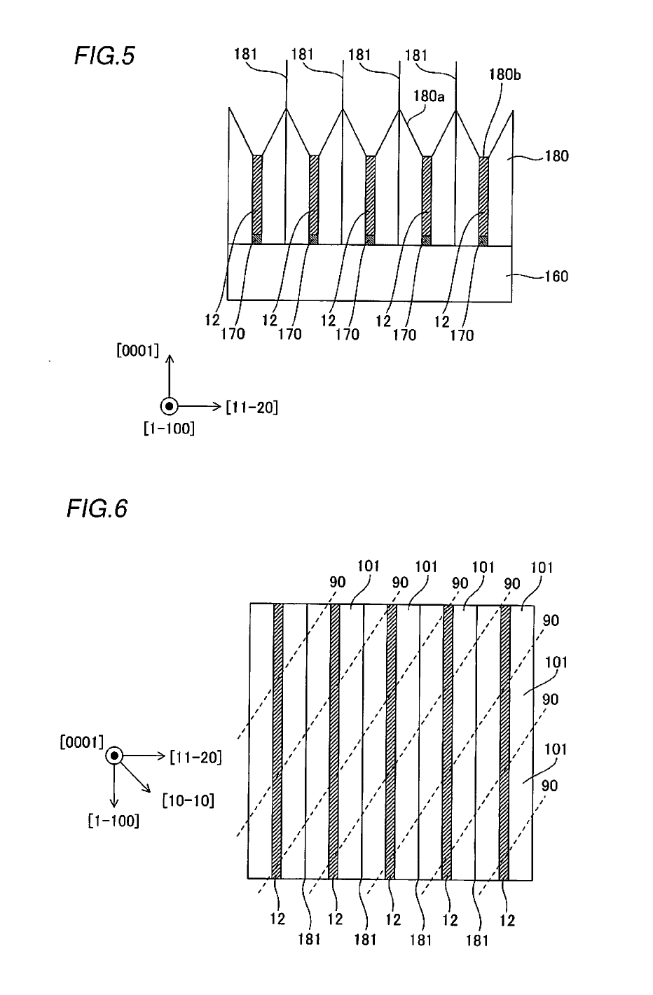

A manufacturing process of the semiconductor laser device 100 of the first embodiment will be now described with reference to FIGS. 5 to 15. FIG. 5 is a sectional view showing a GaN layer formed on a growth substrate, and FIG. 6 is a top plan view showing the GaN layer formed on the growth substrate.

As shown in FIG. 5, a amorphous or polycrystalline GaN layer 170 provided in the form of a striped manner having a longitudinal direction in the [1-100] direction (perpendicular to the plane of FIG. 5) is formed on a GaAs substrate 160 having a (111) plane as a main surface at intervals of about 200 μm in the [11-20] direction. Thereafter a GaN layer 180 is grown on the main surface of the GaAs substrate 160 in the [0001] direction by hydride vapor phase epitaxy (HVPE).

When the GaN layer 180 is grown in the aforementioned manner, the GaN layer 180 on regions on the amorphous or polycrystalline GaN layer 170 includes a large number of dislocations and the GaN layer 180 having a saw blade shaped irregular section, in which the regions are valleys, is formed. Irregular inclined surfaces (facets 180a) of the GaN layer 180 are (11-22) planes. Then, when the growth proceeds in the [0001] direction while maintaining this sectional shape, dislocations existing on the facets 180a move to valleys 180b. Thus, the defect concentration regions 12 are formed on the GaN layer 170 parallel to the (11-20) plane at the intervals of about 200 μm in the [11-20] direction. Thus, the GaN layer 180 having the defect concentration regions 12 with defects concentrated along the (11-20) plane is formed in the aforementioned manner.

Thereafter, the GaAs substrate 160 is removed, and the GaN layer 180 is sliced along a slice plane (broken line 90) parallel to the (10-10) plane inclined by about 30 degrees from the (11-20) plane to the [1-100] direction, as shown in FIG. 6. Thus, a plurality of wafer substrates 101 where the slice planes are upper and lower surfaces are formed. In each wafer substrate 101, the upper and lower surfaces are substantially equal to the (10-10) plane, and the defect concentration regions 12 obliquely extend from the lower surface toward the upper surface. The defect concentration regions 12 extend in the form of the surface in the [0001] direction (perpendicular to the plane of FIG. 6).

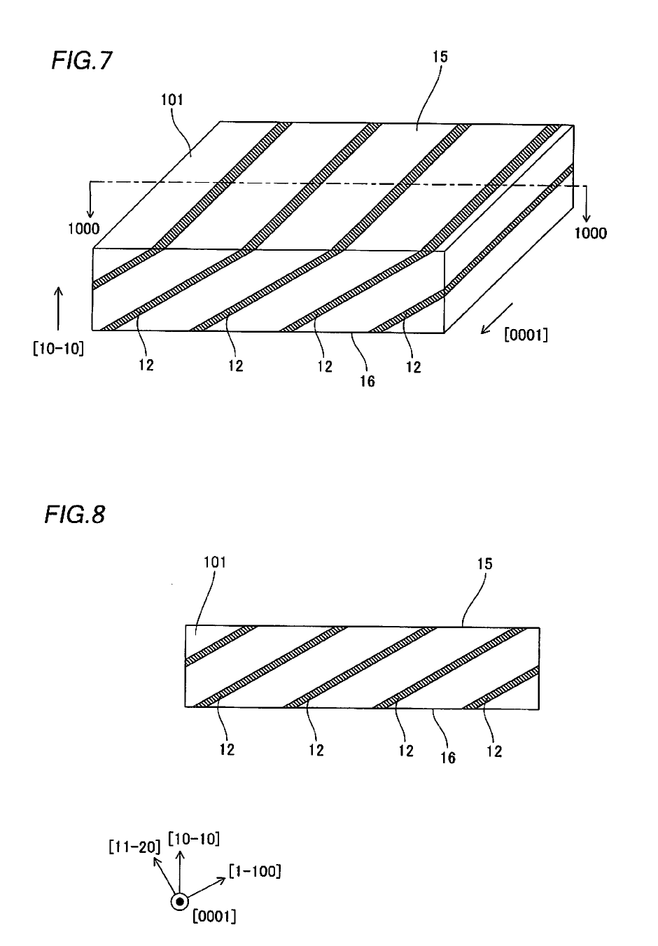

Then, both ends of the sliced wafer substrate 101 are cut perpendicular to a slice plane 90, thereby obtaining the wafer substrate 101 having the defect concentration regions 12 obliquely extending from the lower surface 16 to the upper surface 15, as shown in FIG. 6. FIG. 7 is a perspective view of the wafer substrate 101, and FIG. 8 is a sectional view taken along the one-dot chain line 1000-1000 in the perspective view of the wafer substrate 101 in FIG. 7. As shown in FIG. 7, the defect concentration regions 12 appear on the upper surface 15 of the wafer substrate 101 in a striped manner having a width of at lease about 40 μm and not more than 100 μm in the [0001] direction.

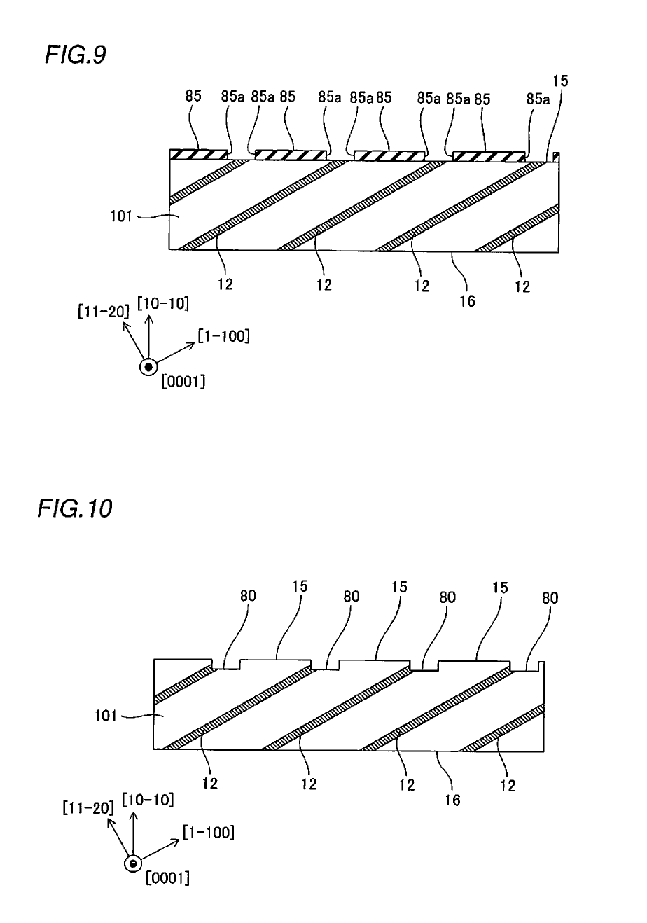

As shown in FIG. 9, a mask 85 made of SiO₂, having striped openings 85a with a width of about 110 μm and extending from the front end side to the rear end side of the wafer substrate 101 is formed in the [0001] direction (perpendicular to the plane in FIG. 9) along the portions where the defect concentration regions 12 appear on the upper surface 15 of the substrate 10. In the mask 85, a width of the openings 85a is larger than that of the portions where the defect concentration regions 12 appear on the upper surface 15 of the wafer substrate 101, and central positions in the width direction of the openings 85a substantially coincide with centers in the width direction of the portions where the defect concentration regions 12 appear. Thus, all of the defect concentration regions 12 appearing on the upper surface 15 of the substrate 10 are located in the openings 85a of the masks 85 at prescribed intervals from ends of the openings 85a.

As shown in FIG. 10, the upper surface of the wafer substrate 101 is etched along the portions where the defect concentration regions 12 appear by reactive ion etching (RIE), thereby forming grooves 80 with a depth of 5 μm and a width of 110 μm on the upper surface of the wafer substrate 101. The depth of the grooves 80 is preferably at least about 3 μm and not more than 5 μm. The width of the grooves 80 is preferably 50 μm to 110 μm to include the portions of the defect concentration regions 12 appearing on the upper surface 15 of the substrate. Thus, the defect concentration regions 12 appear only in the grooves 80, and hence the defect concentration regions 12 do not appear on the upper surface 15 of the wafer substrate 101. The defect concentration regions 12 extend in a direction inclined to the upper surface of the wafer substrate 101, and hence each defect concentration region 12 appearing in the groove 80 appears not only on a bottom surface of the groove 80 but also on an inner side surface on one side.

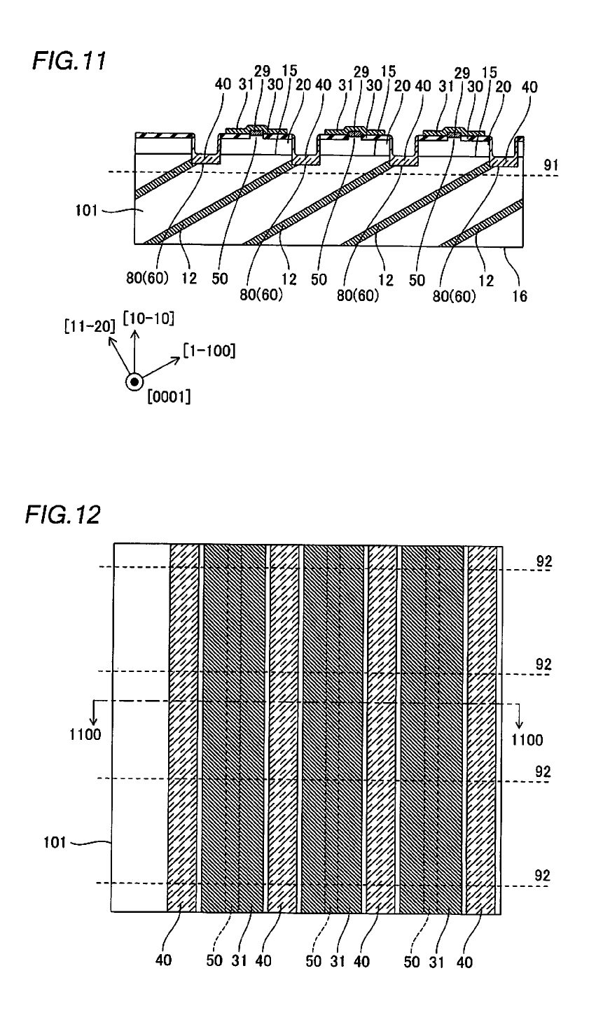

As shown in FIG. 11, the semiconductor device layer 20 for the laser device emitting a blue-violet laser beam having a lasing wavelength of about 405 nm is formed on the wafer substrate 101 provided with the grooves 80 by crystal growth.

A technique of forming the semiconductor device layer 20 made of a nitride-based semiconductor on the wafer substrate 101 by metal organic chemical vapor deposition (MOCVD) will be hereinafter specifically described.

The semiconductor device layer 20 including the buffer layer 21, the n-type cladding layer 22, the n-side carrier blocking layer 23, the light-emitting layer 24, the p-side optical guide layer 25, the p-side carrier blocking layer 26, the p-type cladding layer 27 and the p-side contact layer 28 is formed on each upper surface of the wafer substrate 101 between the grooves 80 by MOCVD (see FIG. 1). More specifically, the buffer layer 21 made of Al_{0.01}Ga_{0.99}N is grown with a thickness of about 1.0 μm on the substrate 10. The n-type cladding layer 22 made of n-type Al_{0.07}Ga_{0.93}N doped with Ge, having a thickness of about 1.9 μm and the n-side carrier blocking layer 23 made of Al_{0.2}Ga_{0.8}N are grown with a thickness of about 20 nm. The light-emitting layer 24 made of an MQW active layer having a multiple quantum well structure and obtained by alternately stacking three quantum well layers made of InₓGa₁₋ₓN and three quantum barrier layers made of In_{y}Ga_{1-y}N is formed. In this embodiment, x>y, and x=0.15 and y=0.02. Thereafter, the p-side optical guide layer 25 made of In_{0.01}Ga_{0.99}N, having a thickness of about 80 nm and the p-side carrier blocking layer 26 made of Al_{0.25}Ga_{0.75}N, having a thickness of about 20 nm are successively grown on the upper surface of the light-emitting layer 24.

The p-type cladding layer 27 made of Al_{0.07}Ga_{0.93}N is grown with a thickness of about 0.45 μm. Then the p-side contact layer 28 made of In_{0.07}Ga_{0.93}N having a thickness of about 30 nm is formed. A plurality of the semiconductor device layers 20 are formed on the wafer substrate 101 made of GaN by MOCVD in the aforementioned manner.

Thereafter, a temperature of the substrate is reduced to a room temperature and the wafer substrate 101 stacked with the semiconductor layers 20 is taken out from a reactor.

Striped masks made of SiO₂ are formed on the upper surface of the semiconductor device layer 20 (p-side contact layer 28) to extend in the [0001] direction. Each mask has a width of about 2 μm, and a central position in a width direction of the mask is located on a position deviated by about 25 μm in a direction where the defect concentration region 12 is inclined from the upper surface 15 to the lower surface with respect to a central position in a width direction of each upper surface 15 of the wafer substrate 101 between the grooves 80. SiO₂ is employed as masks for partially patterning the p-side contact layer 28 and the p-type cladding layer 27 by RIE employing Cl₂ gas, thereby forming the ridge portions 50. In this etching, the p-side contact layer 28 is patterned, and the projecting portions 27a of the p-type cladding layer 27 are formed by leaving a thickness of about 0.05 μm in the p-type cladding layer 27 having a thickness of about 0.45 μm. Thus, each ridge portion 50 constituted by the projecting portion 27a of the p-type cladding layer 27 and the p-side contact layer 28 and having a width of about 2 μm and a height of about 0.4 μm is formed. The ridge portions 50 are formed to extend parallel to the [0001] direction (perpendicular to the plane of the drawing) of the wafer substrate 101.

Thereafter the masks are removed and the p-side ohmic electrodes 29 are formed on the p-side contact layer 28 located on upper surfaces of the ridge portions 50. The current blocking layer 30 made of SiO₂ is so formed as to cover the upper surface of the p-type cladding layer 27 and the side surfaces of the ridges 50 and the p-side ohmic electrodes 29. Thereafter, each p-side pad electrode 31 is formed on the upper surfaces of the p-side ohmic electrode 29 and the current blocking layer 30.

When forming the semiconductor device layer 20, the layer is formed on the overall surface of the wafer substrate 101 formed with the grooves 80. Therefore, the layer is formed also on the bottoms and the inner side surfaces of the grooves 80 of the wafer substrate 101, which becomes the non-device layer 40. The length from the upper surface 15 of the wafer substrate 101 to the bottom surface of each groove 80 (depth of the groove 80) is larger than the thickness of the semiconductor device layer 20. Therefore, the non-device layer 40 having substantially the same thickness as the semiconductor device layer 20 is formed in each groove 80 of the wafer substrate 101, and the semiconductor device layer 20 on the upper surface 15 and the non-device layer 40 on the bottom surface of the groove 80 are linked by the thin layer 40a of the non-device layer 40 formed on the inner side surfaces of the groove 80, as shown in FIG. 11.

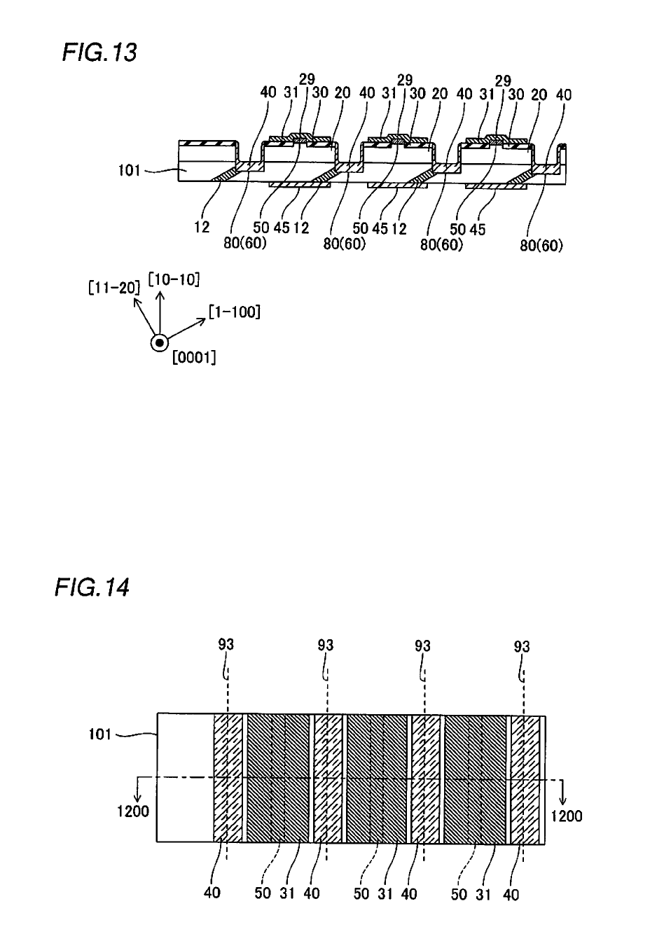

As shown in FIG. 13, the wafer substrate 101 is easily cleaved and have such a small thickness (about 100 μm) that the defect concentration regions 12 do not exist on lower positions of the centers of the ridge portions 50 in the width direction by polishing the lower surface side of the wafer substrate 101 up to a polished position (broken line 91) in FIG. 11. The n-side electrodes 45 are formed on regions below the semiconductor device layer 20 in the lower surface of the wafer substrate 101.

The wafer substrate 101 is cleaved along a cleavage plane (broken line 92) in FIG. 12. The cleavage of the wafer substrate 101 forms the grooves 80 and the scribing grooves in the vicinity thereof along the cleavage plane to avoid the ridge portions 50 by laser scribing, for example, and is performed by applying mechanical force to the wafer substrate 101 to bend to the lower surface side of the wafer substrate 101. FIG. 13 is a sectional view taken along the one-dot chain line 1100-1100 in FIG. 12.

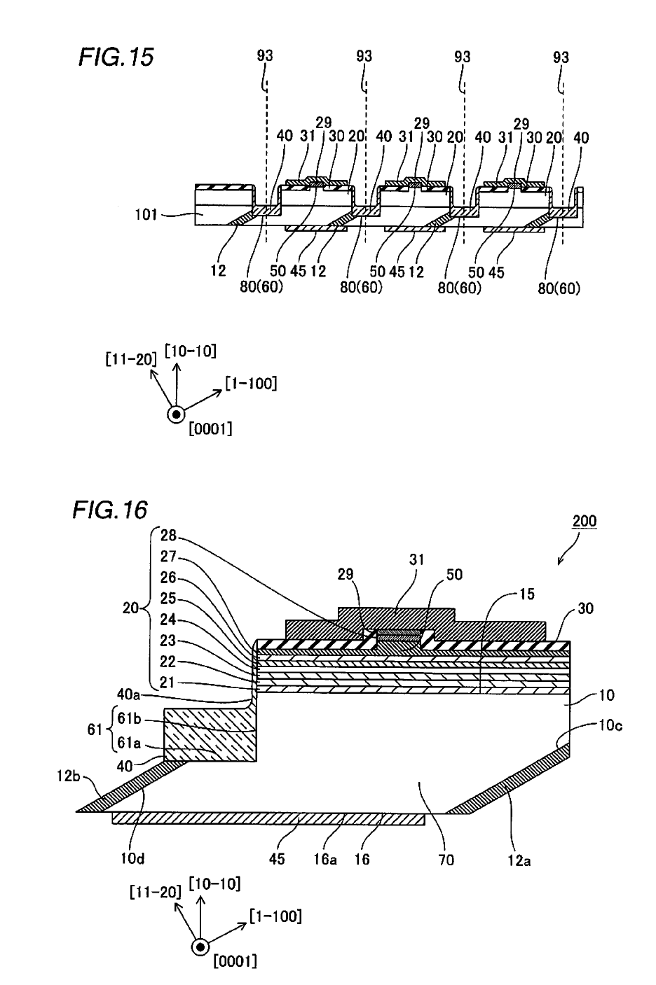

A plurality of the semiconductor device layers 20 are formed on the bar-shaped wafer substrate 101 to be aligned along the cleavage plane in the aforementioned manner, as shown in FIG. 14. FIG. 14 is a top plan view of the bar-shaped wafer substrate 101 where the plurality of the semiconductor device layers 20 are formed to be aligned along the cleavage plane, and FIG. 15 is a sectional view taken along the one-dot chain line 1200-1200 in FIG. 14.

Similarly to the above, scribing grooves are formed around centers in the width direction of the grooves 80 of the bar-shaped wafer substrate 101 along a cut plane (broken line 93) in FIG. 15, and the bar-shaped wafer substrate 101 is divided, thereby forming a plurality of the semiconductor laser devices 100 of the first embodiment. At this time, the divided wafer substrate 101 becomes the substrate 10 of each semiconductor laser device 100, and the grooves 80 become a pair of the recess portions 60 and 61 extending in the [0001] direction from the front facet 10a of the substrate 10 to the rear facet 10b on the both side ends of the upper surface 15 of the substrate 10 (see FIGS. 1 and 3).

The wafer substrate 101 is an example of the “wafer substrate” in the present invention, and the groove 80 is an example of the “groove” in the present invention.

According to the first embodiment, as hereinabove described, the upper surface 15 of the substrate 10 is the (10-10) plane which is the nonpolar plane, and hence a piezoelectric field generated in the light-emitting layer 24 of the semiconductor device layer 20 formed on the upper surface can be reduced. Thus, luminous efficiencies of the semiconductor laser device 100 can be increased.

According to the first embodiment, in the current path region 70 and the non-current path region 71 separated by the defect concentration region 12 of the substrate 10 employed as the boundary, the semiconductor device layer 20 is formed on the upper surface 15 of the substrate 10 on the current path region 70 side and the n-side electrode 45 is formed on the current path surface 16a of the substrate 10 on the current path region 70 side. Thus, a current between the semiconductor device layer 20 and the n-side electrode 45 can flow without traversing the defect concentration region 12, and increase of electric resistance resulting from the defect concentration region 12 can be suppressed.

According to the first embodiment, the defect concentration region 12 extends to the recess portion 60 located on the side end portion of the upper surface 15 formed with the semiconductor device layer 20, whereby the semiconductor device layer 20 and the non-device layer 40 are linked with each other through the thin layer 40a formed on the side surface 60b of the recess portion 60 by the step of the recess portion 60, and propagation of cracks or dislocations from the defect concentration region 12 to the semiconductor device layer 20 can be suppressed.

According to the first embodiment, the center of the ridge portion 50 in the width direction is located above the current path surface 16a on the lower surface 16 of the substrate, whereby a current flowing between the ridge portion 50 and the n-side electrode 45 formed on the current path surface 16a without traversing the defect concentration region 12 is increased, and hence increase of the electric resistance resulting from the defect concentration region 12 can be further suppressed.

According to the first embodiment, the n-side electrode 45 is formed on the lower surface 16 from the current path surface 16a of the substrate 10 to the non-current path surface 16b, whereby a current flows across the defect concentration region 12 from the semiconductor device layer 20 to the n-side electrode 45 on the non-current path surface 16b of the lower surface 16 in addition to the current flowing from the semiconductor device layer 20 to the n-side electrode 45 on the current path surface 16a of the lower surface 16 through the current path region 70, and hence the electric resistance between the semiconductor device layer 20 and the n-side electrode 45 can be further reduced.

According to the first embodiment, the ridge portion 50 is formed to be located above the region except the portion where the defect concentration region 12 appears in the upper surface 15 of the substrate 10, whereby the optical waveguide formed on the lower portion of the ridge portion 50 can be reliably arranged on the upper surface 15 except the portion where the defect concentration region 12 appears. The ridge portion 50 is formed to be located above the region except the portion where the defect concentration region 12 appears in the lower surface 16 of the substrate 10, whereby the optical waveguide can be reliably arranged above the lower surface except the portion where the defect concentration region 12 appears. Consequently, a current can flow while avoiding the defect concentration region 12 having a high resistance, and hence increase of resistance of the current path can be suppressed.

According to the first embodiment, the defect concentration region 12 is formed to extend in the form of the surface along the extensional direction of the ridge portion 50 (optical waveguide), whereby the current path region 70 extending along the extensional direction of the optical waveguide can be easily formed by the defect concentration region 12.

In the manufacturing process of the first embodiment, as hereinabove described, the semiconductor device layer 20 is formed on the upper surface 15 of the wafer substrate 101 formed with the grooves 80 after forming the grooves 80 becoming the recess portions 60 on the portions, where the defect concentration regions 12 appears, of the upper surface 15 of the wafer substrate 101 becoming the substrate 10, whereby the semiconductor device layer 20 formed on the upper surface 15 and the non-device layer 40 formed on the grooves 80 when forming the semiconductor device layer 20 are linked by the thin layer 40a of the non-device layer 40 formed on the side surfaces of the grooves 80. Thus, propagation of cracks or dislocations from the defect concentration regions 12 in the grooves 80 to the semiconductor device layer 20 can be suppressed when forming the semiconductor device layer 20, and the semiconductor device layer 20 having a small number of cracks or defects can be formed.

In the manufacturing process of the first embodiment, the wafer substrate 101 is divided into a plurality of the devices along the grooves 80 which are thin portions of the wafer substrate 101, whereby division can be easily performed and excess force is difficult to be applied to the semiconductor device layer 20 in division, and hence separation of or damage to the semiconductor device layer 20 can be suppressed.

In the manufacturing process of the first embodiment, the mask 85 is so formed that the central positions in the width direction of the portions, where the defect concentration regions 12 appear, on the upper surface 15 of the wafer substrate 101 becoming the substrate 10 and the central positions in the width direction of the openings 85a of the mask 85 for groove formation substantially coincide with each other, whereby the width of the openings 85a of the mask 85 can be set to a minimum width required for removing the portions where the defect concentration regions 12 appear from the upper surface 15, and the upper surface 15 other than the portions where the defect concentration regions 12 appear is not wastefully removed. Thus, the width of the device layer 20 can be increased.

### Second Embodiment

A second embodiment will be now described with reference to FIGS. 6 and 16. Portions identical to those in FIG. 1 are denoted by the same reference numerals, and the description of FIG. 1 is incorporated in description thereof.

As shown in FIG. 16, in a semiconductor laser device 200 of the second embodiment, a substrate 10 is constituted by a current path region 70 having defect concentration regions 12a and 12b on both side facets. The defect concentration regions 12a and 12b are defect concentration regions remaining on the substrate 10 side when dividing the wafer substrate 101 in the vicinity of centers in a thickness direction of the defect concentration regions 12 along the defect concentration regions 12 of the wafer substrate 101 shown in FIG. 6.

As shown in FIG. 16, a recess portion 61 is formed on only one of side ends of an upper surface 15 of the substrate 10. An inclined plane 10c is formed on a lower portion of the side end on a side formed with no recess portion of the substrate 10, and an inclined plane 10d is formed on another side end formed with the recess portion 61 below the recess portion 61.

The inclined plane 10c is inclined in a direction closer to a ridge portion 50 (current injection portion) from the upper surface 15 of the substrate 10 toward a lower surface 16, and the inclined plane 10d is inclined in a direction separated from the ridge portion 50 from the upper surface 15 of the substrate 10 toward the lower surface 16.

The defect concentration regions 12a and 12b are formed along the inclined planes 10c and 10d, respectively, the defect concentration regions 12a are inclined in the direction closer to the ridge portion 50 from the upper surface 15 of the substrate 10 toward the lower surface 16, and the defect concentration region 12b is inclined in the direction separated from the ridge portion 50 from the upper surface 15 of the substrate 10 toward the lower surface 16.

The substrate 10 is constituted only by the current path region 70, and an overall area of the lower surface 16 of the current path region 70 serves as a current path surface 16a.

Each of the defect concentration regions 12a and the 12b is located on outer side surface of the substrate 10, and is a boundary dividing into the current path region 70 and outside of the device (other region).

A central position in a width direction of the ridge portion 50 is located in a direction separated from the side end having the defect concentration region 12a with respect to a central position in a width direction of the upper surface 15 of the substrate 10, and the central position in the width direction of the ridge portion 50 is located above the current path surface 16a.

In the semiconductor laser device 200 of the second embodiment, a non-device layer 40 is formed on a bottom surface 61a and a side surface 61b of the recess portion 61. A semiconductor device layer 20 on the upper surface 15 of the substrate 10 and the non-device layer 40 on the bottom surface 61a are linked through a thin layer 40a thinner than a layer formed on the bottom surface 61a of the non-device layer 40 formed on the side surface 61b.

The overall lower surface 16 of the substrate 10 serves as a current path surface 16a, and an n-side electrodes 45 are formed on the substantially overall lower surface 16 other than the defect concentration regions 12a and 21b.

A manufacturing process of the semiconductor laser device 200 of the second embodiment will be now described with reference to FIGS. 15 to 17.

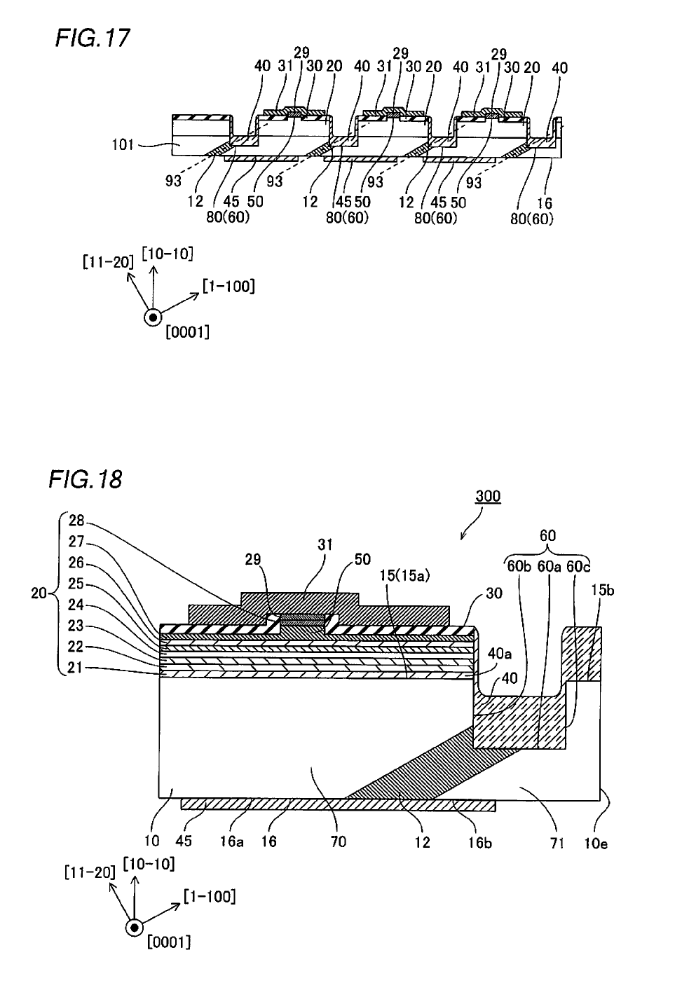

In the semiconductor laser device 200 of the second embodiment of the present invention, the n-side electrodes 45 are formed on the substantially overall lower surface 16 other than the defect concentration regions 12, after polishing the lower surface side of a wafer substrate 101, as shown in FIG. 17. Thereafter, the wafer substrate 101 is divided along a plane along the defect concentration region 12 employed as a cut plane (shown by a broken line 93 in FIG. 17) in place of the cut plane (broken line 93) substantially perpendicular to the wafer substrate 101, with reference to a manufacturing step of the first embodiment shown in FIG. 15, thereby forming a plurality of the semiconductor laser devices 200. Consequently, the semiconductor laser device 200 where the side surfaces of the substrate 10 are constituted by the defect concentration regions 12a and 12b formed on the inclined planes 10c and 10d as shown in FIG. 16 is obtained. The remaining manufacturing process of the second embodiment is similar to that of the aforementioned first embodiment.

According to the second embodiment, as hereinabove described, the semiconductor laser device 200 is divided along the defect concentration region 12, whereby the defect concentration regions 12a and 12b exist only on the side facets of the substrate 10, and the overall upper surfaces 15 and 16 of the substrate 10 are not divided by the defect concentration regions 12. Thus, the substantially overall lower surface 16 of the substrate 10 serves as the current path surface 16a, and a plane area of the n-side electrode 45 on the current path surface 16a can be maximized, and hence electric resistance can be further reduced.

### Third Embodiment

A third embodiment will be now described with reference to FIG. 18. Portions identical to those in FIG. 1 are denoted by the same reference numerals, and the description of FIG. 1 is incorporated in description thereof.

As shown in FIG. 18, in a semiconductor laser device 300 of the third embodiment, a recess portion 60 is formed at a position separated by a prescribed distance from a side facet 10e of a substrate 10 on an upper surface of the substrate 10 to extend in a [0001] direction (perpendicular to the plane of FIG. 18). The recess portion 60 has a bottom surface 60a and both side surfaces 60b and 60c, and a distance between the side facet 10e of the substrate 10 and a side surface 60c of the recess portion 60 is about 50 μm. The upper surface of the substrate 10 is divided into an upper surface 15a formed with a semiconductor device layer 20 having a ridge portion 50 and an upper surface 15b formed with a non-device layer 40 to hold the recess portion 60 therebetween. The non-device layer 40 is a layer formed when forming the semiconductor device layer 20, and has substantially the same layer structure as the semiconductor device layer 20.

The substrate 10 is separated into a current path region 70 and a non-current path region 71 (other region) by a defect concentration region 12 employed as a boundary. The current path region 70 is formed on a region from the upper surface 15a formed with the semiconductor device layer 20 having the ridge portion 50 to a part (current path surface 16a) of a lower surface 16. The non-current path region 71 is formed on a region from the bottom surface 60a of the recess portion 60 and the upper surface 15b formed with the non-device layer 40 to a remaining portion (non-current path surface 16b) of the lower surface 16.

The non-device layer 40 is formed in the recess portion 60 of the substrate 10 and on the upper surface 15b, and a thin layer 40a thinner than a layer formed on the bottom surface 60a is formed also on the side surface 60b of the recess portion 60 and a side facet of the semiconductor device layer 20.

The semiconductor device layer 20 on the upper surface 15a of the substrate 10 and the non-device layer 40 on the bottom surface 60a of the recess portion 60 are lined through the thin layer 40a of the non-device layer 40 formed on the side surface 60b of the recess portion 60, similarly to the aforementioned embodiment.

A central position in a width direction of the ridge portion 50 is located in a direction separated from the side end having the defect concentration region 12 with respect to a central position in a width direction of the upper surface 15a of the substrate 10, and the central position in the width direction of the ridge portion 50 is located above the current path surface 16a.

A manufacturing process of the semiconductor laser device 300 of the third embodiment will be now described with reference to FIGS. 15, 18 and 19.

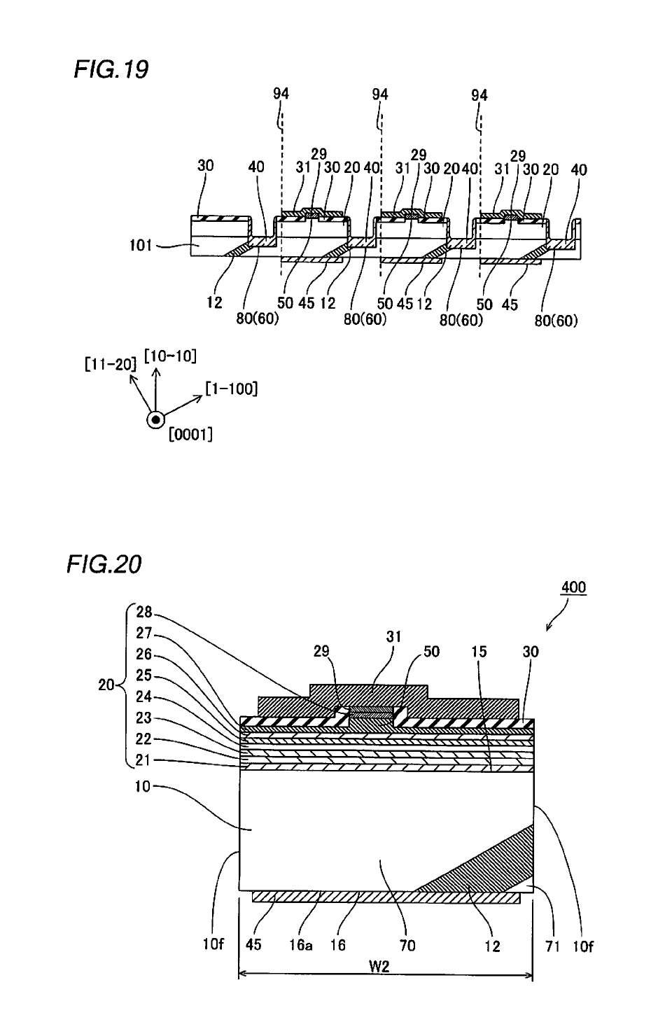

In the semiconductor laser device 300 of the third embodiment of the present invention, scribing grooves are formed along cut planes employing planes extending in the same direction as the grooves 80 as cut planes (shown by a broken line 94 in FIG. 19) in the vicinity of the grooves 80 to divide a wafer substrate 101 in the place of the cut plane (broken line 93) located in the grooves 80 with reference to a manufacturing step of the first embodiment shown in FIG. 15, thereby forming a plurality of the semiconductor laser devices 300. The scribing grooves are formed on regions formed with no p-side pad electrode 31 on the semiconductor device layer 20 and the current blocking layer 30. Consequently, the semiconductor laser device 300 where the recess portion 60 is formed on the position separated by the prescribed distance from the side facet 10e of the substrate 10 as shown in FIG. 18 is obtained. The remaining manufacturing process is similar to that of the aforementioned first embodiment.

According to the third embodiment, as hereinabove described, the device can be divided on the regions where no defect concentration region 12 appears, and hence breakage of the device, such as break-up by chipping a substrate side facet on the defect concentration region can be suppressed, and a yield can be improved.

### Fourth Embodiment

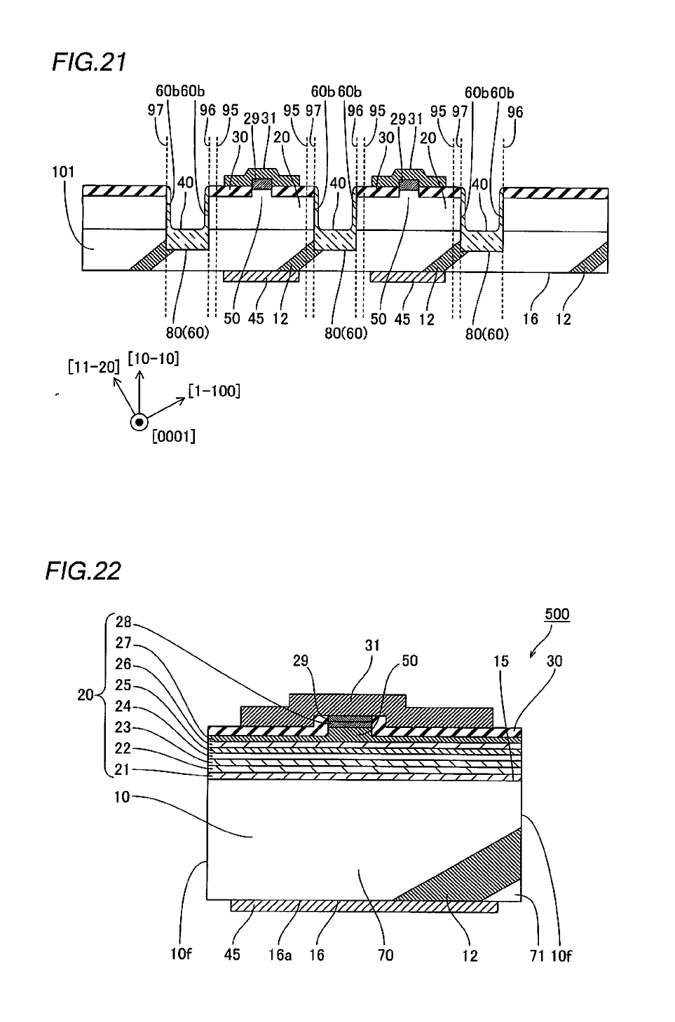

A fourth embodiment will be described with reference to FIGS. 20 and 21. Portions identical to those in FIG. 1 are denoted by the same reference numerals, and the description of FIG. 1 is incorporated in description thereof.

As shown in FIG. 20, in a semiconductor laser device 400 of the fourth embodiment, ends in a width direction of the device is formed to have a pair of side facets 10f extending in a direction substantially perpendicular to an upper surface 15 from a semiconductor device layer 20 side toward the substrate 10. In other words, recess portions 60 and 61 formed in each of the aforementioned first to third embodiments do not remain on both ends in a width direction of the semiconductor laser device 400.

In other words, in the manufacturing process in the fourth embodiment, as shown in FIG. 21, scribing grooves are formed at positions on a side closer to the ridge portions 50 than the grooves 80 on a lower surface 16 of a bar-shaped wafer substrate 101 (semiconductor device layer 20) and the bar-shaped wafer substrate 101 is thereafter divided along this cut plane (broken line 95), thereby forming a plurality of the semiconductor laser devices 400.

In the manufacturing process of the fourth embodiment, as hereinabove described, the bar-shaped wafer substrate 101 is divided at the positions provided on the side closer to the ridge portions 50 than the grooves 80, whereby the defect concentration region 12 can be formed on the semiconductor laser device 400 to be exposed on a side facet 10f of the substrate 10, and hence a width W2 (see FIG. 20) of the semiconductor laser device 400 can be rendered smaller. At this time, the defect concentration region 12 does not appear on the upper surface 15, and hence a current path region 70 of the substrate 10 formed with the semiconductor device layer 20 on an upper side can be widely ensured.

### Fifth Embodiment

A fifth embodiment will be described with reference to FIGS. 21 and 22. Portions identical to those in FIG. 1 are denoted by the same reference numerals, and the description of FIG. 1 is incorporated in description thereof.

As shown in FIG. 22, in a semiconductor laser device 500 of the fifth embodiment, ends in a width direction of the device is formed to have a pair of side facets 10f extending in a direction substantially perpendicular to an upper surface 15 from a semiconductor device layer 20 side toward the substrate 10, similarly to the semiconductor laser device 400 of the aforementioned fourth embodiment. In the fifth embodiment, a side surface 60b of the recess portion 60 and a side surface 61b of the recess portion 61 are formed to be exposed on parts of the side facets 10f.

In other words, in the manufacturing process of the fifth embodiment, as shown in FIG. 21, scribing grooves are formed at positions corresponding to corners (connecting portions of inner side surfaces and bottom portions) of grooves 80 on a lower surface 16 of the bar-shaped wafer substrate 101, and the bar-shaped wafer substrate 101 is divided on the cut planes (broken lines 96 and 97 along both inner side surfaces of the grooves 80), thereby forming a plurality of the semiconductor laser devices 500.

In the manufacturing process of the fifth embodiment, as hereinabove described, the bar-shaped wafer substrate 101 is divided on bottom portions of the grooves 80, whereby division is easily performed due to a small thickness of the wafer substrate 101, and excess force is difficult to be applied to the semiconductor device layer 20 in division, and hence separation of or damage to the semiconductor device layer 20 can be suppressed.

In the manufacturing process of the fifth embodiment, the wafer substrate 101 is divided on the cut surfaces (broken lines 96 and 97) along the inner side surfaces of the grooves 80, whereby the wafer substrate 101 can be easily divided along positions formed with the inner side surfaces of the grooves 80.

### Sixth Embodiment

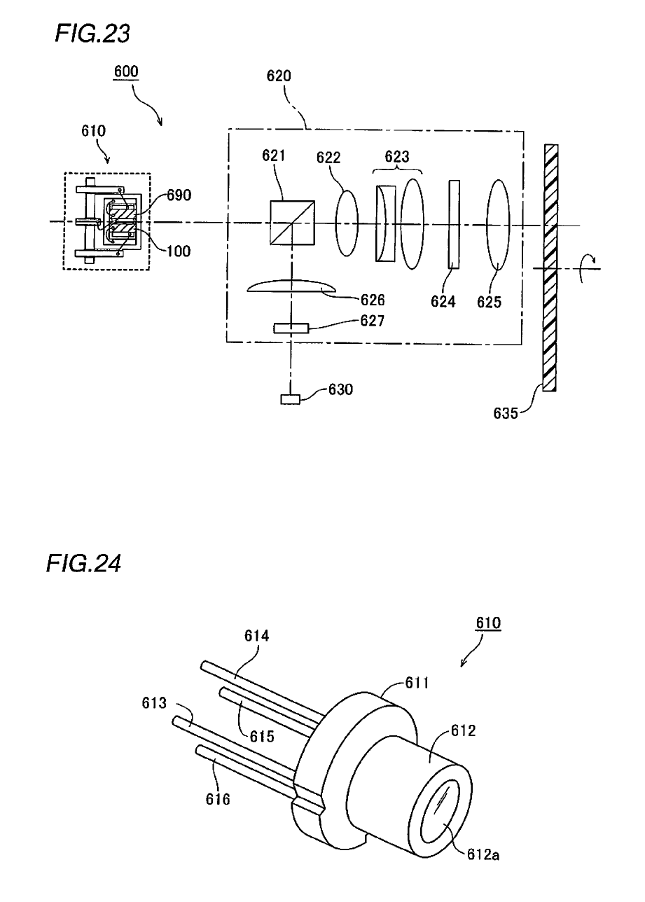

An optical pickup 600 according to a sixth embodiment of the present invention will be described with reference to FIGS. 23 to 25. The optical pickup 600 is an example of the “light apparatus” in the present invention.

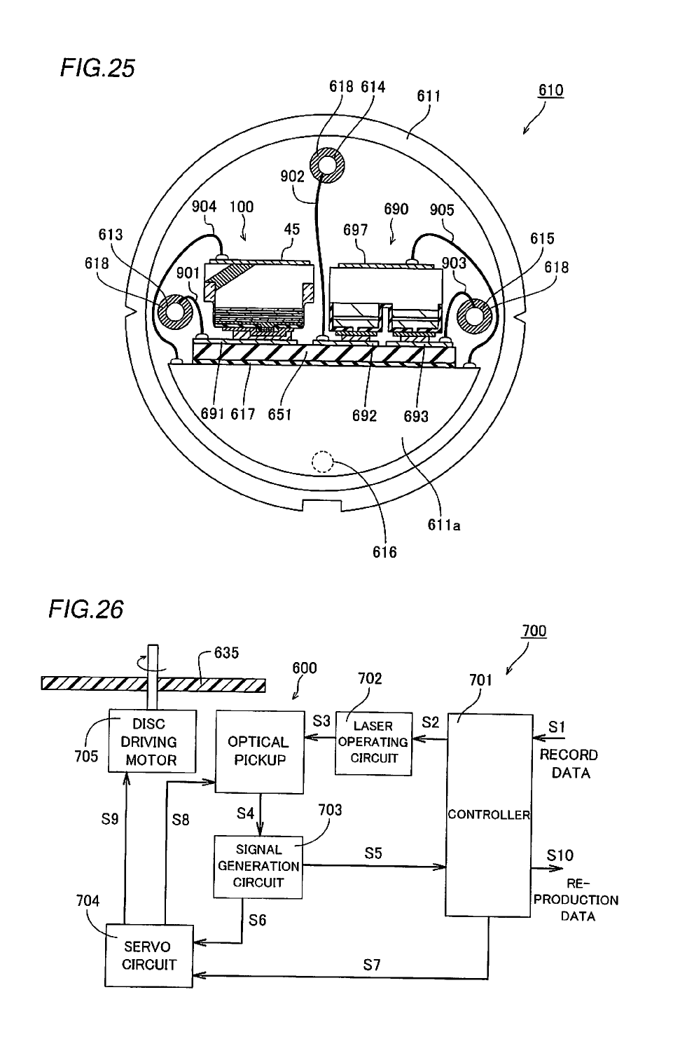

The optical pickup 600 according to the sixth embodiment of the present invention comprises a semiconductor laser apparatus 610 mounted with the semiconductor laser device 100 (see FIG. 25) according to the aforementioned first embodiment and a red/infrared two-wavelength semiconductor laser device 690 (see FIG. 25), an optical system 620 adjusting a laser beam emitted from the semiconductor laser apparatus 610, and a light detection portion 630 receiving the laser beam, as shown in FIG. 23.

The semiconductor laser apparatus 610 has a base 611 made of a conductive material, a cap 612 arranged on a front surface of the base 611, leads 613, 614, 615 and 616 mounted on a rear surface of the base 611, as shown in FIGS. 24 and 25. A header 611a (see FIG. 25) is integrally formed with the base 611 on the front surface of the base 611.

The semiconductor laser device 100 is arranged on an upper surface of the header 611a, and a submount (substrate) 651 (see FIG. 25) and the header 611a are fixed by a bonding layer 617 (see FIG. 25) made of resin. An optical window 612a (see FIG. 24) transmitting a laser beam emitted from the semiconductor laser device 100 is mounted on a front surface of the cap 612, and the semiconductor laser device 100 and the red/infrared two-wavelength semiconductor laser device 690 inside the base 611 covered with the cap 612 is sealed by the cap 612.

As shown in FIG. 25, the leads 613 to 615 pass through the base 611 and are fixed to be electrically insulated from each other through insulating members 618. The lead 613 is electrically connected to a pad electrode 691 through a wire 901, and the lead 614 is electrically connected to a pad electrode 692 through a wire 902. The lead 615 is electrically connected to a pad electrode 693 through a wire 903. An n-side electrode 45 of the semiconductor laser device 100 and a portion, not placed with the submount 651, of an upper surface of a header 611a are electrically connected through a wire 904. An n-side electrode 697 of the red/infrared two-wavelength semiconductor laser device 690 and a portion, not placed with the submount 651, of the upper surface of the header 611a are electrically connected through a wire 905. The lead 616 is integrally formed with the base 611. Thus, the lead 616, the n-side electrode 45 and n-side electrode 697 are electrically connected through the header 611a, and cathode common connection of the semiconductor laser device 100 and the red/infrared two-wavelength semiconductor laser device 690 is achieved.

The optical system 620 has a polarizing beam splitter (polarizing BS) 621, a collimator lens 622, a beam expander 623, a λ/4 plate 624, an objective lens 925, a cylindrical lens 626 and an optical axis correction device 627, as shown in FIG. 23.

The polarizing BS 621 totally transmits the laser beam emitted from the semiconductor laser apparatus 610 and totally reflects the laser beam returned from an optical disc 635. The collimator lens 622 converts the laser beam from the semiconductor laser device 100 transmitting through the polarizing BS 621 to parallel light. The beam expander 623 includes a concave lens, a convex lens and an actuator (not shown). The actuator has a function of correcting a state of wavefront of the laser beam emitted from the semiconductor laser apparatus 610 by changing a distance of the concave lens and the convex lens in response to a servo signal from the servo circuit described later.

The λ/4 plate 624 converts a linearly-polarized laser beam converted to substantially parallel light by the collimator lens 622 to circularly-polarized light. The λ/4 plate 624 converts the circularly-polarized laser beam returned from the optical disc 635 to linearly-polarized light. A direction of polarization of linearly-polarized light in this case is perpendicular to a direction of linear polarization of the laser beam emitted from the semiconductor laser apparatus 610. Thus, the laser beam returned from the optical disc 635 is totally reflected by the polarizing BS 621. The objective lens 625 converges the laser beam transmitted through the λ/4 plate 624 on a surface (recording layer) of the optical disc 635. The objective lens 625 is movable in a focus direction, a tracking direction and a tilt direction in response to a servo signal (a tracking servo signal, a focus servo signal and a tilt servo signal) from the servo circuit described later by an objective lens actuator (not shown).

The cylindrical lens 626, optical axis correction device 627 and the light detection portion 630 are arranged along an optical axis of the laser beam totally reflected by the polarizing BS 621. The cylindrical lens 626 gives astigmatic action to an incident laser beam. The optical axis correction device 627 is formed by diffraction grating and so arranged that a spot of zero-order diffracted light of each of blue-violet, red and infrared laser beams transmitted through the cylindrical lens 626 coincides on a detection region of the light detection portion 630 described later.

The light detection portion 630 outputs a reproduced signal on the basis of intensity distribution of a received laser beam. The light detection portion 630 has a prescribed patterned detection region to obtain the reproduced signal as well as a focus error signal, a tracking error signal and a tilt error signal. Thus, the optical pickup 600 comprising the semiconductor laser apparatus 610 is formed.

In this optical pickup 600, the semiconductor laser apparatus 610 is so formed that blue-violet, red and infrared laser beams independently emit from the semiconductor laser device 100 and the red/infrared two-wavelength semiconductor laser device 690 by independently applying voltages between the lead 616 and the leads 613 to 615, respectively. As hereinabove described, the laser beams emitted from the semiconductor laser apparatus 610 are adjusted by the polarizing BS 621, the collimator lens 622, the beam expander 623, the λ/4 plate 624, the objective lens 625, cylindrical lens 626 and the optical axis correction device 627, and thereafter irradiated on the detection region of the light detection portion 630.

When information recorded in the optical disc 635 is reproduced, the laser beams are applied to the recording layer of the optical disc 635 and the reproduced signal output from the light detection portion 630 can be obtained while controlling respective laser power emitted from the semiconductor laser device 100 and the red/infrared two-wavelength semiconductor laser device 690 to be constant. The actuator of the beam expander 623 and the objective lens actuator driving the objective lens 625 can be feedback-controlled by the focus error signal, the tracking error signal and the tilt error signal simultaneously output.

When information is recorded in the optical disc 635, the laser beams are applied to the optical disc 635 while controlling laser power emitted from the semiconductor laser device 100 and the red/infrared two-wavelength semiconductor laser device 690 on the basis of information to be recorded. Thus, the information can be recorded in the recording layer of the optical disc 635. Similarly to the above, the actuator of the beam expander 623 and the objective lens actuator driving the objective lens 625 can be feedback-controlled by the focus error signal, the tracking error signal and the tilt error signal output from the light detection portion 630.

Thus, record in the optical disc 635 and reproduction can be performed with the optical pickup 600 comprising the semiconductor laser apparatus 610.

In the optical pickup 600 of the sixth embodiment, the semiconductor laser device 100 is mounted in the semiconductor laser apparatus 610, and hence the optical pickup comprising the semiconductor laser device 100 in which a piezoelectric field is reduced to improve luminous efficiencies, and increase in electric resistance resulting from the defect concentration region 12 is suppressed can be obtained.

### Seventh Embodiment

An optical disc apparatus 700 according to a seventh embodiment of the present invention will, be described with reference to FIGS. 23 and 26. The optical pickup 700 is an example of the “light apparatus” in the present invention.

The optical disc apparatus 700 according to the seventh embodiment of the present invention comprises the optical pickup 600 (see FIG. 23) according to the aforementioned sixth embodiment, a controller 701, a laser operating circuit 702, a signal generation circuit 703, a servo circuit 704 and a disc driving motor 705, as shown in FIG. 26.

Recorded data S1 generated on the basis of information to be recorded in the optical disc 635 is inputted in the controller 701. The controller 701 outputs a signal S2 to the laser operating circuit 702 and outputs a signal S7 to the servo circuit 704 in response to the record data S1 and a signal S5 from the signal generation circuit 703 described later. The controller 701 outputs reproduction data S10 on the basis of the signal S5, as described later. The laser operating circuit 702 outputs a signal S3 controlling laser power emitted from the semiconductor laser apparatus 610 in the optical pickup 600 in response to the aforementioned signal S2. In other words, the semiconductor laser apparatus 610 is formed to be driven by the controller 701 and the laser operating circuit 702.

In the optical pickup 600, a laser beam controlled in response to the aforementioned signal S3 is applied to the optical disc 635, as show in FIG. 26. A signal S4 is output from the light detection portion 630 in the optical pickup 600 to the signal generation circuit 703. The optical system 620 (the actuator of the beam expander 623 and the objective lens actuator driving the objective lens 625) in the optical pickup 600 is controlled by a servo signal S8 from the servo circuit 704 described layer. The signal generation circuit 703 performs amplification and arithmetic processing for the signal S4 output from the optical pickup 600, to output the first output signal S5 including a reproduced signal to the controller 701 and to output a second output signal S6 performing the aforementioned feed-back control of the optical pickup 600 and rotational control, described later, of the optical disc 635 to the servo circuit 704.

As shown in FIG. 26, the servo circuit 704 outputs the servo signal S8 controlling the optical system 620 in the optical pickup 600 and a motor servo signal S9 controlling the disc driving motor 705 in response to the second output signal S6 and the signal S7 from the signal generation circuit 703 and the controller 701. The disc driving motor 705 controls a rotational speed of the optical disc 635 in response to the motor servo signal S9.

When information recorded in the optical disc 635 is reproduced, a laser beam having a wavelength to be applied is first selected by means identifying types (CD, DVD, BD, etc.) of the optical disc 635 which is not described here. Then, the signal S2 is so output from the controller 701 to the laser operating circuit 702 that an intensity of the laser beam having the wavelength to be emitted from the semiconductor laser apparatus 610 in the optical pickup 600 is constant. Further, the signal S4 including a reproduced signal is output from the light detection portion 630 to the signal generation circuit 703 by functioning the semiconductor laser apparatus 610, the optical system 620 and the light detection portion 630 of the optical pickup 600 described above, and the signal generation circuit 703 outputs the signal S5 including the reproduced signal to the controller 701. The controller 701 processes the signal S5, so that the reproduced signal recorded in the optical disc 635 is extracted and output as the reproduction data S10. Information such as images and sound recorded in the optical disc 635 can be output to a monitor, a speaker and the like with this reproduction data S10, for example. Feed-back control of each portion is performed on the basis of the signal S4 from the light detection portion 630.

When information is recorded in the optical disc 635, the laser beam having the wavelength to be applied is selected by the means identifying types (CD, DVD, BD, etc.) of the optical disc 635, similarly to the above. Then, the signal S2 is output from the controller 701 to the laser operating circuit 702 in response to the record data S1 responsive to recorded information. Further, information is recorded in the optical disc 635 by functioning the semiconductor laser apparatus 610, the optical system 620 and the light detection portion 630 of the optical pickup 600 described above, and feed-back control of each portion is performed on the basis of the signal S4 from the light detection portion 630.

Thus, record in the optical disc 635 and reproduction can be performed with the optical disc apparatus 700.

In the optical disc apparatus 700 according to the seventh embodiment, the semiconductor laser device 100 is mounted in the semiconductor laser apparatus 610, and hence the optical disc apparatus 700 comprising the semiconductor laser device 100 in which a piezoelectric field is reduced to improve luminous efficiencies, and increase in electric resistance resulting from the defect concentration region 12 is suppressed can be obtained.

### Eighth Embodiment

A structure of a projector 800 according to an eighth embodiment of the present invention will be described with reference to FIGS. 21, 27 and 28. In the projector 800, each of semiconductor laser devices constituting a RGB three-wavelength semiconductor laser device 810 is substantially simultaneously turned on. The optical pickup 800 is an example of the “light apparatus” in the present invention.

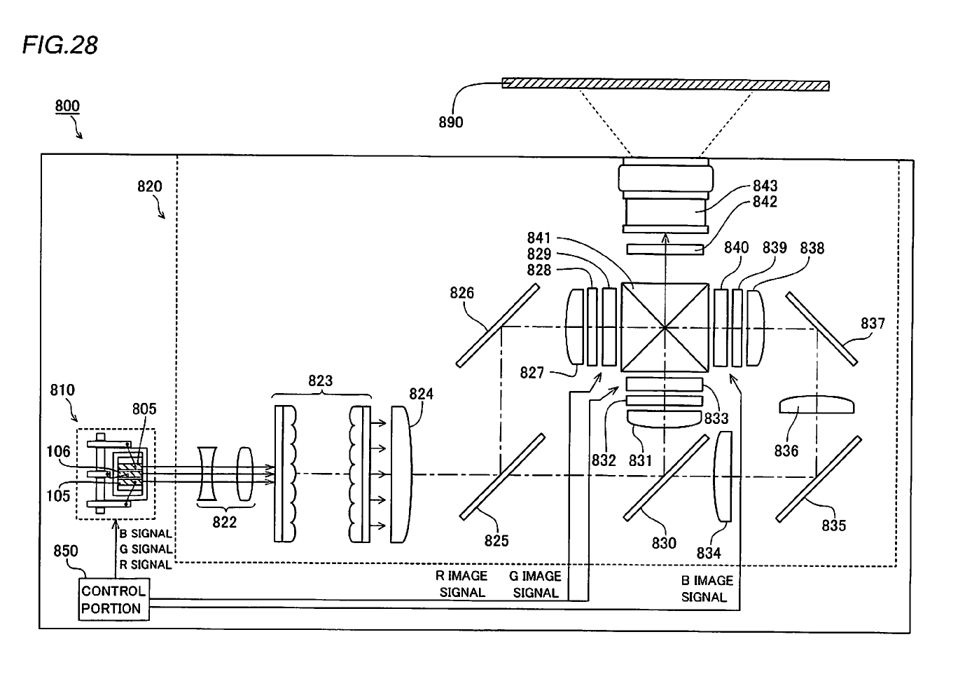

The projector 800 according to the eighth embodiment of the present invention comprises the RGB three-wavelength semiconductor laser device 810, an optical system 820 consisting of a plurality of optical components and a control portion 850 controlling the RGB three-wavelength semiconductor laser device 810 and the optical system 820, as shown in FIG. 28. Thus, laser beams emitted from the RGB three-wavelength semiconductor laser device 810 are modulated by the optical system 820 and thereafter projected on an external screen 890 or the like.

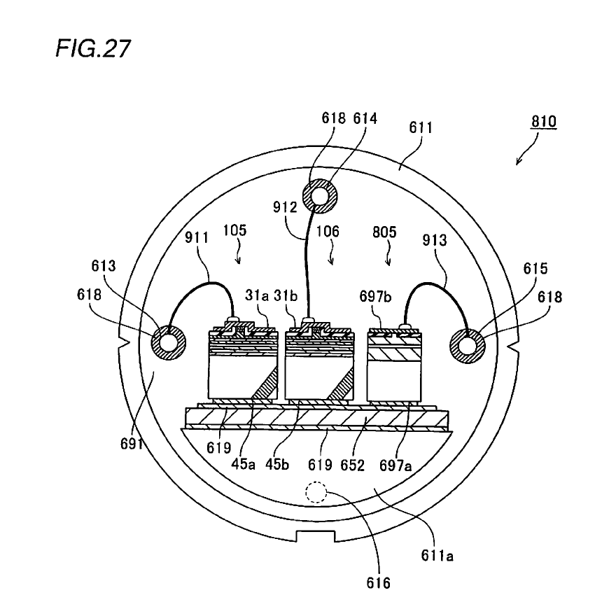

As shown in FIG. 27, the RGB three-wavelength semiconductor laser device 810 is so formed that a red semiconductor laser device 805 having a lasing wavelength of about 655 nm, a green semiconductor laser device 105 having a lasing wavelength of about 530 nm and a blue semiconductor laser device 106 having a lasing wavelength of about 480 nm are placed on an upper surface of a submount 652 made of a conductive material such as Cu. The green semiconductor laser device 105 and the blue semiconductor laser device 106 are formed through a manufacturing process similar to that (see FIG. 21) of the aforementioned fourth embodiment. In the red, green and blue semiconductor laser devices 805, 105 and 106, n-side electrodes 45a, 45b and 697a which the respective devices have are fixed on the upper surface of the submount 652 through a bonding layer 619 made of Au—Sn solder or the like. A lower surface of the submount 652 is bonded onto a header 611a through the bonding layer 619.

A lead 613 is electrically connected to a p-side pad electrode 31a conducting with a p-type semiconductor layer of the green semiconductor laser device 105 through a wire 911, and a lead 614 is electrically connected to a p-side pad electrode 31b conducting with a p-type semiconductor layer of the blue semiconductor laser device 106 through a wire 912. A lead 615 is electrically connected to a p-side electrode 697b of the red semiconductor laser device 805 through a wire 913. Thus, the lead 616 and the n-side electrodes 45a, 45b and 697a are electrically connected through the header 611a, and cathode common connection of the red, green and blue semiconductor laser devices 805, 105 and 106 is achieved.

In the optical system 820, the laser beams emitted from the RGB three-wavelength semiconductor laser device 810 are converted to parallel beams having prescribed beam diameters by a dispersion angle control lens 822 consisting of a concave lens and a convex lens, and thereafter introduced into a fly-eye integrator 823, as shown in FIG. 28. The fly-eye integrator 823 is so formed that two fly-eye lenses consisting of fly-eye lens groups face each other, and provides a lens function to the beams introduced from the dispersion angle control lens 822 so that light quantity distributions in incidence upon liquid crystal panels 829, 833 and 840 are uniform. In other words, the beams transmitted through the fly-eye integrator 823 are so adjusted that the same can be incident upon the liquid crystal panels 829, 833 and 840 with spreads of aspect ratios (16:9, for example) corresponding to the sizes of the liquid crystal panels 829, 833 and 840.

The beams transmitted through the fly-eye integrator 823 are condensed by a condenser lens 824. In the beams transmitted through the condenser lens 824, only the red beam is reflected by a dichroic mirror 825, while the green and blue beams are transmitted through the dichroic mirror 825.

The red beam is parallelized by a lens 827 through a mirror 826, and thereafter incident upon the liquid crystal panel 829 through an incidence-side polarizing plate 828. The liquid crystal panel 829 is driven in response to a red image signal (R image signal), thereby modulating the red beam.

In the beams transmitted through a dichroic mirror 825, only the green beam is reflected by the dichroic mirror 830, while the blue beam is transmitted through the dichroic mirror 830.

The green beam is parallelized by a lens 831, and thereafter incident upon the liquid crystal panel 833 through an incidence-side polarizing plate 832. The liquid crystal panel 833 is driven in response to a green image signal (G image signal), thereby modulating the green beam.

The blue beam transmitted through the dichroic mirror 830 passes through a lens 834, a mirror 835, a lens 836 and a mirror 837, is parallelized by a lens 838, and thereafter incident upon the liquid crystal panel 840 through an incidence-side polarizing plate 839. The liquid crystal panel 840 is driven in response to a blue image signal (B image signal), thereby modulating the blue beam.

The red, green and blue beams modulated by the liquid crystal panels 829, 833 and 840 are synthesized by a dichroic prism 841, and thereafter introduced into a projection lens 843 through an emission-side polarizing plate 842. The projection lens 843 stores a lens group for imaging projected light on a projected surface (screen 890) and an actuator for adjusting the zoom and the focus of the projected image by partially displacing the lens group in an optical axis direction.

In the projector 800, the control portion 850 controls to supply stationary voltages as an R signal related to driving of the red semiconductor laser device 805, a G signal related to driving of the green semiconductor laser device 105 and a B signal related to driving of the blue semiconductor laser device 106 to the respective laser devices of the RGB three-wavelength semiconductor laser device 810. Thus, the red, green and blue semiconductor laser devices 805, 105 and 106 of the RGB three-wavelength semiconductor laser device 810 are substantially simultaneously oscillated. The control portion 850 is formed to control the intensities of the beams emitted from the red, green and blue semiconductor laser devices 805, 105 and 106 of the RGB three-wavelength semiconductor laser device 810, thereby controlling the hue, brightness etc. of pixels projected on the screen 890. Thus, the control portion 850 projects a desired image on the screen 890.

The projector 800 loaded with the RGB three-wavelength semiconductor laser device 810 according to the first embodiment of the present invention is constituted in the aforementioned manner.

### Ninth Embodiment

A structure of a projector 900 according to a ninth embodiment of the present invention will be described with reference to FIGS. 27, 29 and 30. In the projector 900, each of semiconductor laser devices constituting a RGB three-wavelength semiconductor laser device 810 is turned on in a time-series manner. The optical pickup 900 is an example of the “light apparatus” in the present invention.

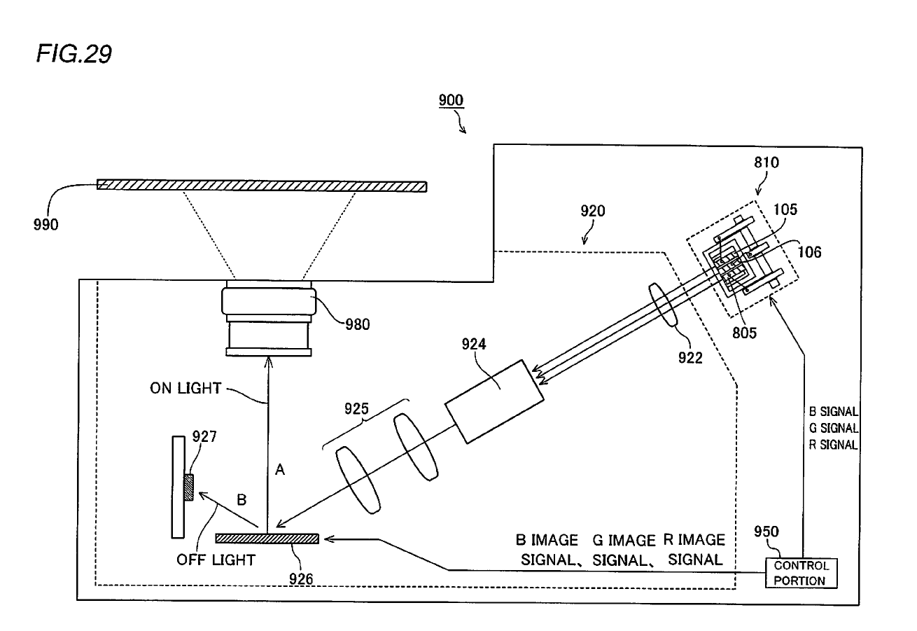

The projector 900 according to the ninth embodiment of the present invention comprises the RGB three-wavelength semiconductor laser device 810 employed in the aforementioned eighth embodiment, an optical system 920, and a control portion 950 controlling the RGB three-wavelength semiconductor laser device 810 and the optical system 920, as shown in FIG. 29. Thus, beams emitted from the RGB three-wavelength semiconductor laser device 810 are modulated by the optical system 920 and thereafter projected on a screen 990 or the like.

In the optical system 920, the beams emitted from the RGB three-wavelength semiconductor laser device 810 are converted to parallel beams by a lens 922, and thereafter introduced into a light pipe 924.

The light pipe 924 has a specular inner surface, and the laser beams are repeatedly reflected by the inner surface of the light pipe 924 to travel in the light pipe 924. At this time, intensity distributions of the beams of respective colors emitted from the light pipe 924 are uniformized due to multiple reflection in the light pipe 924. The beams emitted from the light pipe 924 are introduced into a digital micromirror device (DMD) 926 through a relay optical system 925.

The DMD 926 consists of a group of small mirrors arranged in the form of a matrix. The DMD 926 has a function of expressing (modulating) gradation of each pixel by switching a direction of reflection of light on each pixel position between a first direction A toward a projection lens 960 and a second direction B deviating from the projection lens 980. Light (ON-light) incident upon each pixel position and reflected in the first direction A is introduced into the projection lens 980 and projected on a projected surface (screen 990). On the other hand, light (OFF-light) reflected by the DMD 926 in the second direction B is not introduced into the projection lens 980 but absorbed by a light absorber 927.

In the projector 900, the control portion 950 controls to supply a pulse voltage to the RGB three-wavelength semiconductor laser device 810, thereby dividing the red, green and blue semiconductor laser devices 805, 105 and 106 of the RGB three-wavelength semiconductor laser device 810 in a time-series manner and cyclically driving the same one by one. Further, the control portion 950 is so formed that the DMD 926 of the optical system 920 modulates light in response to the gradations of the respective pixels (R, G and B) in synchronization with the driving of the red, green and blue semiconductor laser devices 805, 105 and 106.

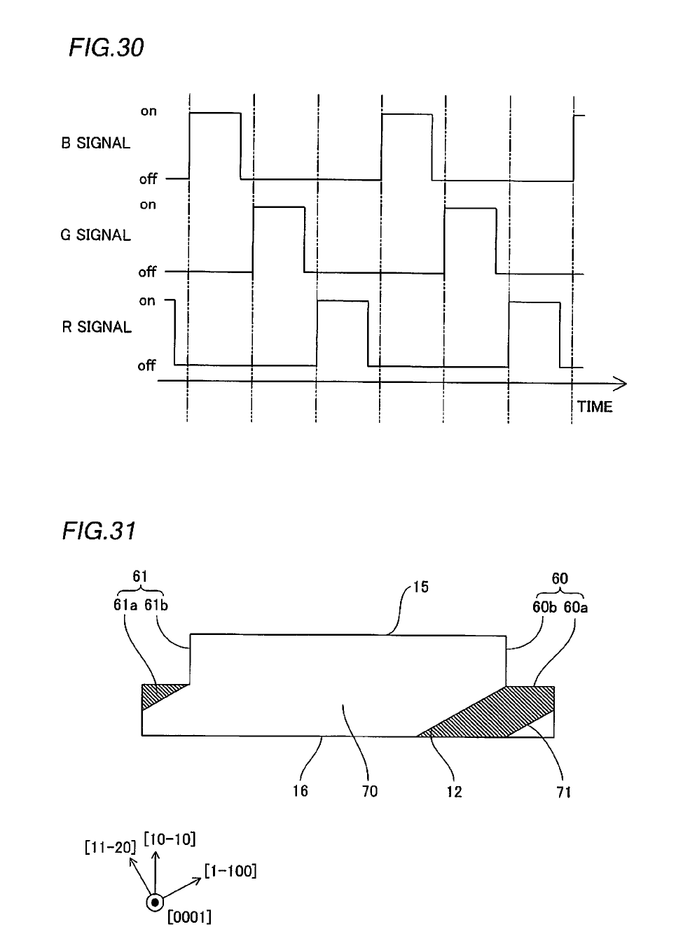

More specifically, an R signal related to driving of the red semiconductor laser device 805 (see FIG. 27), a G signal related to driving of the green semiconductor laser device 105 (see FIG. 27) and a B signal related to driving of the blue semiconductor laser device 106 (see FIG. 27) are divided in a time-series manner not to overlap with each other and supplied to the respective laser devices of the RGB three-wavelength semiconductor laser device 810 by the control portion 950 (see FIG. 29), as shown in FIG. 30. In synchronization with the B, G and R signals, the control portion 950 outputs a B image signal, a G image signal and an R image signal to the DMD 926.

Thus, the blue semiconductor laser device 106 emits a blue beam on the basis of the B signal in a timing chart shown in FIG. 30, while the DMD 926 modulates the blue beam at this timing on the basis of the B image signal. Further, the green semiconductor laser device 105 emits a green beam on the basis of the G signal output subsequently to the B signal, and the DMD 926 modulates the green beam at this timing on the basis of the G image signal. In addition, the red semiconductor laser device 805 emits a red beam on the basis of the R signal output subsequently to the G signal, and the DMD 926 modulates the red beam at this timing on the basis of the R image signal. Thereafter the blue semiconductor laser device 106 emits the blue beam on the basis of the B signal output subsequently to the R signal, and the DMD 926 modulates the blue beam again at this timing on the basis of the B image signal. The aforementioned operations are so repeated that an image formed by application of the laser beams based on the B, G and R image signals is projected on the projected surface (screen 990).

The projector 900 loaded with the RGB three-wavelength semiconductor laser device 810 according to the ninth embodiment of the present invention is constituted in the aforementioned manner.

The aforementioned first to ninth embodiments must be considered as illustrative in all points and not restrictive. The range of the present invention is shown not by the above description of the embodiments but by the scope of claims for patent, and all modifications within the meaning and range equivalent to the scope of claims for patent are included.

For example, while the defect concentration region 12 is formed along the (11-20) plane in the aforementioned first embodiment, the present invention is not restricted to this. In the present invention, the defect concentration region 12 may be formed along a (H, K, −H−K, 0) plane ((when at least either one of H and K is a nonzero integer, which is the same as the following).

The defect concentration region 12 may be a region formed by gathering threading dislocations in the form of a surface in each of the aforementioned first to ninth embodiments.

While the defect concentration region 12 penetrates from the recess portion 60 of the substrate 10 to the lower surface 16 in each of the aforementioned first to third embodiments, the present invention is not restricted to this. In the present invention, the defect concentration region 12 may be extend from the semiconductor device layer 20 to the n-side electrode 45 across the current path to such a degree that increase of electric resistance is caused, and the defect concentration region 12 may not partially penetrate from the recess portion 60 of the substrate 10 to the lower surface 16.

While the upper surface 15 of the substrate 10 is the (10-10) plane which is the nonpolar plane in each of the aforementioned first to ninth embodiments, the present invention is not restricted to this. In the present invention, when the defect concentration region 12 is formed along a (H, K, −H−K, 0) plane, the upper surface 15 of the substrate 10 may be a nonpolar plane inclined by at least 30 degrees not more than about 60 degrees from a [H, K, −H−K, 0] direction to a [K, −H, H−K, 0] direction about the axis along the [0001] direction. For example, when the defect concentration region 12 is formed along the (11-20) plane, the upper surface 15 of the substrate 10 may be a nonpolar plane between a (2-1-10) plane and a (10-10) plane inclined by at least about 30 degrees not more than about 60 degrees from the [1-20] direction to the [1-100] direction about the axis along the [0001] direction. Alternatively, when the defect concentration region 12 is formed along a (1-100) plane, the upper surface 15 of the substrate 10 may be a nonpolar plane between the (2-1-10) plane and the (10-10) plane inclined by at least about 30 degrees not more than about 60 degrees from the [1-100] direction to the [11-20] direction about the axis along the [0001] direction. In particular, a piezoelectric field can be hardly generated in the nitride-based semiconductor device layer when the upper surface 15 of the substrate 10 is the nonpolar plane.

While the upper surface 15 of the substrate 10 is the (10-10) plane which is the nonpolar plane in each of the aforementioned first to ninth embodiments, the present invention is not restricted to this. In the present invention, when the defect concentration region 12 is formed along the (H, K, −H−K, 0) plane, the upper surface 15 of the substrate 10 may be a plane inclined by at least about 30 degrees not more than about 75 degrees from a [H, K, −H−K, 0] direction to the [0001] direction about an axis along the [K, −H, H−K, 0] direction. Alternatively, when the defect concentration region 12 is formed along the (H, K, −H−K, 0) plane, the upper surface 15 of the substrate 10 may be a plane inclined by at least about 30 degrees not more than about 75 degrees from a [H, K, −H−K, 0] direction to a [0001-1] direction about the axis along the [K, −H, H−K, 0] direction.

While the defect concentration region 12 appears on both of the bottom surface 60a and the side surface 60b of the recess portion 60 in each of the aforementioned first and third embodiments, the present invention is not restricted to this. For example, the defect concentration region 12 may appear only on the bottom surfaces 60a and 61a of the recess portions 60 and 61 as in a first modification shown in FIG. 31.

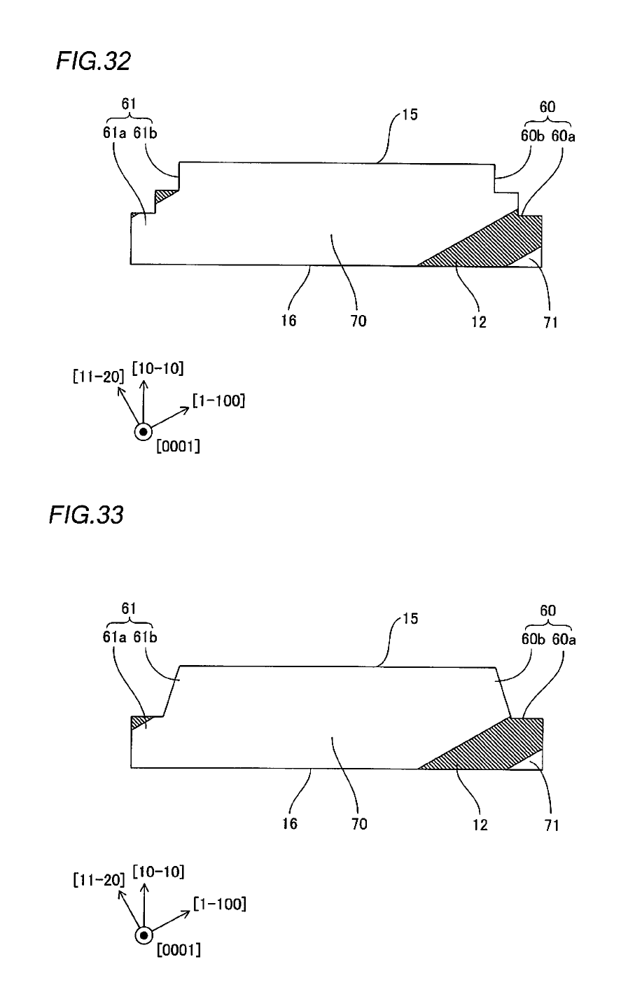

While the recess portions 60 and 61 have rectangular sectional shapes in each of the aforementioned first to third embodiments, the present invention is not restricted to this. For example, the portions may have stepped shapes having steps from the bottom surfaces 60a and 61a of the respective recess portions 60 and 61 to the upper surface 15 as in a second modification shown in FIG. 32.

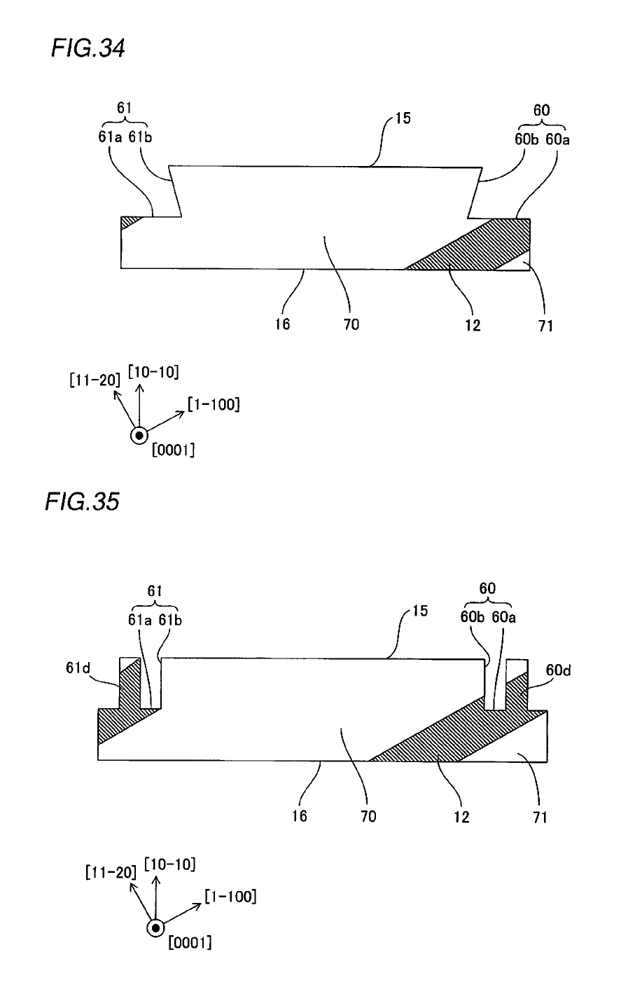

While the recess portions 60 and 61 have rectangular sectional shapes in each of the aforementioned first to third embodiments, the present invention is not restricted to this. For example, the side surfaces 60b and 61b of the respective recess portions 60 and 61 may have mesa sectional shapes consisting of inclined planes as in a third modification shown in FIG. 33 and a fourth modification shown in FIG. 34. At this time, angles formed by the bottom surfaces 60a and 61a and the side surfaces 60b and 61b of the recess portions 60 and 61 are obtuse angles in the shapes shown in FIG. 33, angles formed by the bottom surfaces 60a and 61a and the side surfaces 60b and 61b of the recess portions 60 and 61 are acute angles in the shapes shown in FIG. 34.

While the recess portions 60 and 61 have rectangular sectional shapes in each of the aforementioned first to fourth embodiments, the present invention is not restricted to this. For example, the bottom surfaces 60a and 61a of the respective recess portions 60 and 61 may partially have projecting portions 60d and 61d as in a fifth modification shown in FIG. 35.

While the device layer 20 and the non-device layer 40 are linked with each other by the thin layer 40a of the non-device layer 40 in each of the aforementioned first to ninth embodiments, the present invention is not restricted to this. In the present invention, the thin layer 40a may be cut in the middle between the device layer 20 and the non-device layer 40, and the device layer 20 and the non-device layer 40 may be separated.

While the “nitride-based semiconductor device” of the present invention is applied to the semiconductor laser device in each of the aforementioned first to ninth embodiments, a LED device or a field-effect transistor (FET) device may be formed by employing the substrate 10 similar to that of each of the aforementioned first and second embodiments. In this case, a leak current resulting from cracks or defects in the active layer can be suppressed in a power device requiring a normally-off operation.

While the semiconductor layer device 500 including no recess portion 60 is formed by dividing the substrate 101 on the cut planes (broken lines 96 and 97) along the both inner side surfaces of each groove 80 in the aforementioned fifth embodiment, the present invention is not restricted to this. In the present invention, the semiconductor laser device including the recess portion 60 may be formed by dividing the substrate 101 on the cut plane (broken line 96 or 97) along one of the inner side surfaces of each groove 80, as shown in FIG. 21. In this case, the substrate 101 is divided on the cut plane (broken line 96) along the inner side surface including no defect concentration region 12 among the inner side surfaces of the groove 80, whereby breakage of the semiconductor laser device caused by chipping the substrate 101 on the defect concentration region 12 can be suppressed, and hence a yield can be improved.

What is claimed is:

1. A nitride-based semiconductor device comprising:
a substrate made of a nitride-based semiconductor;
a device layer made of the nitride-based semiconductor formed on said substrate; and
an electrode formed on a surface of said substrate opposite to said device layer, wherein
said substrate includes:
a first surface having a nonpolar plane or a semipolar plane,
a second surface which is a surface opposite to said first surface,
a defect concentration region extending in a direction inclined with respect to a normal direction of said first surface and penetrating to said second surface, and
a current path region having said first surface formed with said device layer and said second surface and separated from other region of said substrate by said defect concentration region employed as a boundary,
said defect concentration region is not exposed on said first surface, and
said electrode is formed on said second surface in said current path region.

2. The nitride-based semiconductor device according to claim 1, wherein
said device layer includes a current injection portion, and
a center in a width direction of said current injection portion is located above said second surface in the said current path region.

3. The nitride-based semiconductor device according to claim 1, wherein
said substrate further includes a non-current path region as said other region, and
said electrode is formed on a region from said second surface in said current path region to said second surface in said non-current path region.

4. The nitride-based semiconductor device according to claim 1, wherein
said device layer includes a current injection portion,
said defect concentration region is inclined in a direction closer to said current injection portion toward said second surface, and
a center in a width direction of said current injection portion is located in a direction separated from said defect concentration region with respect to a center in a width direction of said first surface.

5. The nitride-based semiconductor device according to claim 1, wherein
said substrate further includes a recess portion formed on a side end side of said first surface, and
said defect concentration region penetrates from said recess portion to said second surface.

6. The nitride-based semiconductor device according to claim 5, wherein
a depth of said recess portion is larger than a thickness of said device layer.

7. The nitride-based semiconductor device according to claim 1, wherein
said first surface is a (10-10) plane, a (2-1-10) plane, or a plane substantially equal to a plane equivalent to these planes.

8. The nitride-based semiconductor device according to claim 1, wherein
said defect concentration region is formed substantially parallel to a (H, K, −H−K, 0) plane (when at least either one of H and K is a nonzero integer).

9. A light apparatus comprising:
a nitride-based semiconductor device including a substrate made of a nitride-based semiconductor, a light-emitting device layer made of the nitride-based semiconductor formed on said substrate and an electrode formed on a surface of said substrate opposite to said light-emitting device layer; and
an optical system controlling light emitted from said nitride-based semiconductor device, wherein
said substrate has:
a first surface having a nonpolar plane or a semipolar plane,
a second surface which is a surface opposite to said first surface,
a defect concentration region extending in a direction inclined with respect to a normal direction of said first surface from said first surface toward said second surface and penetrating to said second surface, and
a current path region having said first surface formed with said light-emitting device layer and said second surface and separated from other region of said substrate by said defect concentration region employed as a boundary,
said defect concentration region is exposed on said first surface, and
said electrode is formed on said second surface in said current path region.

10. A method of manufacturing a nitride-based semiconductor device, comprising steps of:
forming a wafer substrate made of a nitride-based semiconductor having defect concentration regions extending in a direction inclined with respect to a normal direction of a first surface and penetrating from said first surface having a nonpolar plane or a semipolar plane to a second surface which is a surface opposite to said first surface;
forming a device layer made of the nitride-based semiconductor on said first surface; and
dividing said wafer substrate into a plurality of devices, wherein
said dividing step includes a step of dividing said wafer substrate so as not to expose said defect concentration regions on said first substrates of said devices.

11. The method of manufacturing a nitride-based semiconductor device according to claim 10, further comprising a step of forming grooves on portions, where said defect concentration regions appear, of said first surface in advance of said step of forming said device layer on said first surface of said wafer substrate.

12. The method of manufacturing a nitride-based semiconductor device according to claim 10, wherein
said dividing step includes a step of dividing said wafer substrate in said grooves on said grooves.

13. The method of manufacturing a nitride-based semiconductor device according to claim 12, wherein
said dividing step includes a step of dividing said wafer substrate on cut planes along inner side surfaces of said grooves.

14. The method of manufacturing a nitride-based semiconductor device according to claim 13, wherein
said dividing step includes a step of dividing said wafer substrate on the cut planes along said inner side surfaces not including said defect concentration regions.

15. The method of manufacturing a nitride-based semiconductor device according to claim 11, wherein
said dividing step includes a step of dividing said wafer substrate so that said devices do not include said grooves.

16. The method of manufacturing a nitride-based semiconductor device according to claim 11, wherein
a depth of each of said grooves is larger than a thickness of said device layer.

17. The method of manufacturing a nitride-based semiconductor device according to claim 10, wherein
said dividing step includes a step of dividing said wafer substrate on regions, where said defect concentration regions do not appear, of said first surface.

18. The method of manufacturing a nitride-based semiconductor device according to claim 10, wherein
said dividing step includes a step of exposing said defect concentration regions on side facets of said wafer substrate.

19. The method of manufacturing a nitride-based semiconductor device according to claim 10, wherein
said dividing step includes a step of exposing said defect concentration regions on both side facets of said wafer substrate by dividing said wafer substrate along said defect concentration regions.
